(19) United States
(12) Patent Application Publication
(10) Pub. No.: US 2024/0336637 A1
(43) Pub. Date: Oct. 10, 2024

(54) LOW REFRACTIVE INDEX COMPOUNDS AND USES THEREOF

(71) Applicants: WUHAN TIANMA MICROELECTRONICS CO., LTD., Wuhan (CN); WUHAN TIANMA MICROELECTRONICS CO., LTD. SHANGHAI BRANCH, Shanghai (CN)

(72) Inventor: Wenpeng DAI, Shanghai (CN)

(73) Assignees: WUHAN TIANMA MICROELECTRONICS CO., LTD., Wuhan (CN); WUHAN TIANMA MICROELECTRONICS CO., LTD. SHANGHAI BRANCH, Shanghai (CN)

(21) Appl. No.: 18/744,722

(22) Filed: Jun. 17, 2024

(30) Foreign Application Priority Data
Oct. 23, 2023 (CN) 202311385670.5

(51) Int. Cl. C07F 7/08; H10K 50/858

(52) U.S. Cl. CPC C07F 7/081; C07F 7/0812; H10K 50/858

(57) ABSTRACT

Provided is a compound with low refractive index, having a structure represented by Formula I. The compounds with low refractive index provided by the present disclosure contain fluorine, cyano or alkyl substituents with large steric hindrance. When paired with a compound with high refractive index as a double-layer CPL material in an OLED, the light extraction efficiency and luminous efficacy of the top-emitting organic optoelectronic device are improved, the angle dependence of the light emission of OLED is alleviated, while water and oxygen in the external environment are effectively blocked to protect the OLED display panel from water and oxygen erosion, and the color shift problem is effectively reduced.

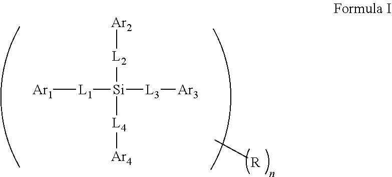

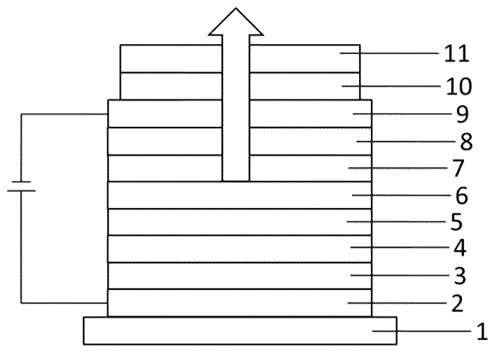

### CROSS REFERENCE TO RELATED APPLICATIONS

This application claims the priority of Chinese Patent Application No. 202311385670.5, filed on Oct. 23, 2023, and the disclosure of which is hereby incorporated by reference.

### FIELD

The present disclosure relates to the field of organic electroluminescence, and in particular to low refractive index compounds and uses thereof.

### BACKGROUND

OLED (organic light-emitting diode) has made great progress after decades of development, of which the internal quantum efficiency is close to 100% while the external quantum efficiency remains around 20%. This is due to factors such as substrate mode loss, surface plasmon loss, and waveguide effects, which confine most of the light inside the light-emitting device, leading to significant energy loss.

In a top-emitting device, an organic capping layer (CPL) is evaporated onto the semi-transparent metal electrode Al to adjust the optical interference distance, suppress external light reflection, and reduce extinction caused by surface plasma energy movement, to improve light extraction efficiency and luminous efficacy.

Designing a double-layer CPL can enhance the efficiency of the device and reduce power consumption. The double-layer CPL is typically composed of a low-refractive compound and a high-refractive compound. However, the current double-layer CPL material, which is formed by a low-refractive index compound and a high-refractive index compound, does not meet the requirements for improving current efficiency and reducing color shift.

### SUMMARY

In view of this, the problem to be solved by the present disclosure is to provide low refractive index compounds and uses thereof, which can be paired with a compound with high refractive index to serve as a double-layer CPL material in an OLED device, therefore improve the luminous efficacy of the device and effectively reduce the color shift problem.

The present disclosure provides a compound with low refractive index, having a structure represented by Formula I:

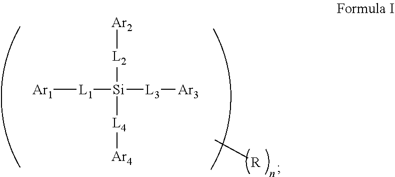

In one embodiment, L₁-L₄ are independently selected from the group consisting of a single bond, a substituted or unsubstituted C6-C18 arylene, and a substituted or unsubstituted C5-C18 heteroarylene;
at least one of Ar₁-Ar₄ is selected from structures represented by Formula II-Formula V, and the others are independently selected from the group consisting of substituted or unsubstituted C6-C30 aryl and substituted or unsubstituted C3-C30 heteroaryl;

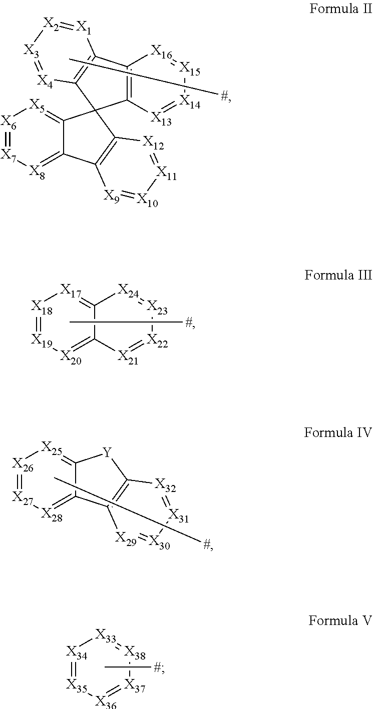

X₁-X₃₈ are independently CH or N;
Y is selected from the group consisting of CR₁R₂, O and S;
R₁ and R₂ are independently H or C1-C3 alkyl;
R is selected from the group consisting of F, alkyl containing F, CN, substituted or unsubstituted C6-C30 aryl, and substituted or unsubstituted C3-C30 heteroaryl; and a substituent of the C6-C30 aryl or the C3-C30 heteroaryl is selected from the group consisting of CN, F, C1-C5 alkyl containing F, and a combination thereof;
n is the number of R and n>1; and
# indicates a linking position.

The present disclosure provides a display panel comprising an organic light-emitting diode, and the organic light-emitting diode comprises an anode, a cathode arranged oppositely, a capping layer on one side of the cathode away from the anode, and an organic layer provided between the anode and the cathode; and the capping layer comprises at least one of the above compounds with low refractive index.

The present disclosure provides a display device comprising the above display panel.

Compared with the prior art, the compounds with low refractive index provided by the present disclosure contain fluorine, cyano or an alkyl substituent with large steric hindrance. When paired with a compound with high refractive index, it can be used as a double-layer CPL material in an OLED device, which can improve the light extraction efficiency and luminous efficacy of the top-emitting organic optoelectronic device, alleviate the angle dependence of the OLED device for light emission, effectively block water and oxygen in the external environment, protect the OLED display panel from water and oxygen erosion, and effectively reduce the color shift problem.

### BRIEF DESCRIPTION OF DRAWINGS

The FIGURE shows a schematic diagram of the organic light-emitting diode provided by the present disclosure.

### DETAILED DESCRIPTION

The present disclosure provides a compound with low refractive index, having a structure represented by Formula I:

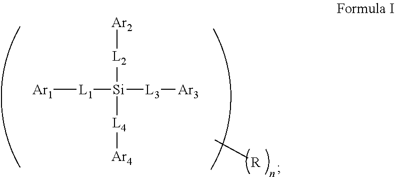

In one embodiment, L₁-L₄ are independently selected from the group consisting of a single bond, a substituted or unsubstituted C6-C18 arylene, and a substituted or unsubstituted C5-C18 heteroarylene;
at least one of Ar₁-Ar₄ is selected from structures represented by Formula II-Formula V, and the others are independently selected from the group consisting of substituted or unsubstituted C6-C30 aryl and substituted or unsubstituted C3-C30 heteroaryl;

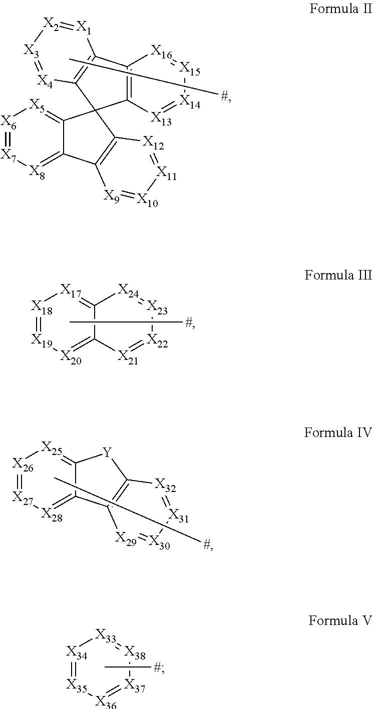

X₁-X₃₈ are independently CH or N;
Y is selected from the group consisting of CR₁R₂, O and S;
R₁ and R₂ are independently H or C1-C3 alkyl;
R is selected from the group consisting of F, alkyl containing F, CN, substituted or unsubstituted C6-C30 aryl, and substituted or unsubstituted C3-C30 heteroaryl; and a substituent of the C6-C30 aryl or the C3-C30 heteroaryl is selected from the group consisting of CN, F, C1-C5 alkyl containing F, and a combination thereof;
n is the number of R and n>1; and
# indicates a linking position.

In one embodiment, L₁-L₄ are independently selected from the group consisting of a single bond, substituted or unsubstituted monocyclic arylene, monocyclic 5- to 6-membered heteroarylene, a group formed by connecting monocyclic arylene and monocyclic 5- to 6-membered heteroarylene through a single bond, a group formed by a fusion of monocyclic arylene and monocyclic 5- to 6-membered heteroarylene, and a group formed by a fusion of monocyclic 5- to 6-membered heteroarylene.

In one embodiment, L₁-L₄ are independently selected from the group consisting of a single bond, substituted or unsubstituted monocyclic arylene, monocyclic 5- to 6-membered heteroarylene, a group formed by connecting 1 or 2 monocyclic arylene and 1 or 2 monocyclic 5- to 6-membered heteroarylene through a single bond, a group formed by a fusion of 1 or 2 monocyclic arylene and 1 or 2 monocyclic 5- to 6-membered heteroarylene, and a group formed by a fusion of 2 or 3 monocyclic 5- to 6-membered heteroarylene.

The heteroatom of the 5- to 6-membered heteroarylene is selected from the group consisting of N, O, S, and a combination thereof.

In one embodiment, L₁-L₄ are independently selected from the group consisting of a single bond, substituted or unsubstituted phenylene, pyridinylene, pyrimidinylene, pyrazinylene, pyridazinylidene, triazinylidene, biphenylene, naphthylene, quinolinylidene, isoquinolinylidene, quinoxalinylidene and quinazolinylidene.

In one embodiment, L₁-L₄ are independently selected from the group consisting of a single bond,

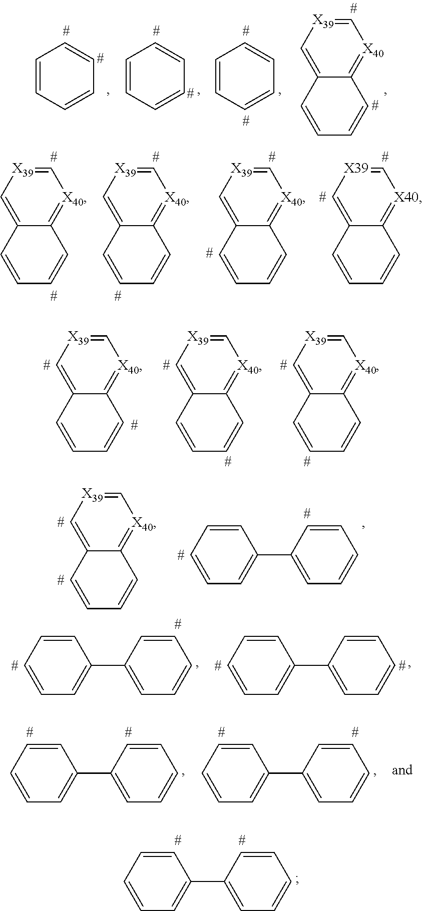

X₃₉ and X₄₀ are independently CH or N; and
# indicates a linking position.

R represents a substituent group in the structure of the compound represented by Formula I. R might replace one or more hydrogen atoms in Ar₁-Ar₄, and might also replace one or more hydrogen atoms in L₁-L₄.

In one embodiment, R represents that one or more hydrogen atoms in Ar₁-Ar₄ are substituted by R.

In one embodiment, any one structure of Ar₁-Ar₄ might have a substituent group R.

In one embodiment, any two structures of Ar₁-Ar₄ might respectively have a substituent group R.

In one embodiment, the two structures are Ar₁ and Ar₃, or Ar₂ and Ar₄.

In one embodiment, any three structures of Ar₁-Ar₄ might respectively have a substituent group R.

In one embodiment, all Ar₁-Ar₄ might respectively have a substituent group R.

In one embodiment, R is selected from the group consisting of F, C1-C5 alkyl containing 1-3 F atoms, CN, substituted or unsubstituted phenyl, substituted or unsubstituted pyridyl; and a substituent of phenyl or pyridyl is selected from the group consisting of CN, F, CF₃, CHF₂, CH₂F, and a combination thereof.

In the present disclosure, the above-mentioned fluorine-containing groups are introduced into the compounds with low refractive index, which can significantly reduce the refractive index of the compounds.

In one embodiment, the phenyl or pyridyl of the compounds has more than one substituents, and the more than one substituents are arranged in meta position. Such arrangement helps to further greatly reduce the refractive index of the compounds.

In one embodiment, R is selected from the group consisting of F, CN, CHF₂, CH₂F, CF₃,

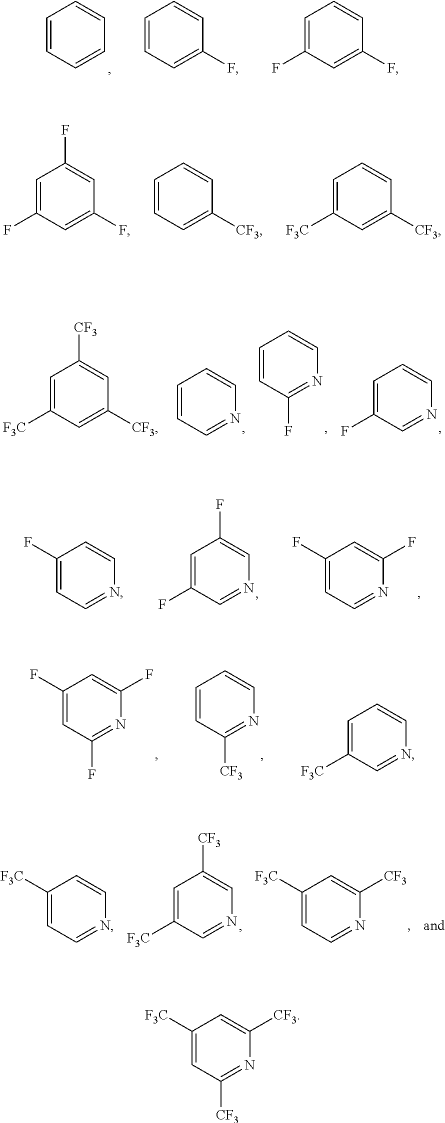

In one embodiment, any one or more of L₁-L₄ and Ar₁-Ar₄ are multi-substituted groups containing multiple R, and the multiple R are arranged in meta position.

In one embodiment, at least one of the substituent R in the compounds with low refractive index is an F-containing group or CN.

n is the number of R. In one embodiment, n is an integer selected from 1 to 8.

In one embodiment, n is 1, 2, 3, 4, 5, 6, 7 or 8.

When there is more than one R in the compound with low refractive index, the substituent groups R may be the same or different.

In one embodiment, the total number of F atoms in the substituent R of the compound with low refractive index is 1 to 9.

In one embodiment, the total number of F atoms in the substituent R of the compound with low refractive index is 3 to 9.

In one embodiment, the total number of F atoms in the substituent R of the compound with low refractive index is 6 to 9.

In one embodiment, the total number of CN group in the substituent R of the compound with low refractive index is 1 to 3.

By controlling the number of F atom or the number of CN group, the refractive index of the above compounds with low refractive index can be better adjusted.

In one embodiment, X₁-X₁₆ are all CH, or one or two of X₁-X₁₆ are N, and the others are CH; and the structure represented by Formula II is connected to parent structure through C atom.

In one embodiment, among the above X₁-X₁₆, one of X₁-X₄ is N, and one of X₁₃-X₁₆ is N; or one of X₅-X₈ is N, and one of X₉-X₁₂ is N.

In one embodiment, X₁₇-X₂₄ are all CH, or one or two of X₁₇-X₂₄ are N, and the others are CH; and the structure represented by Formula III is connected to any one of L₁-L₄ of parent structure through any C atom of Formula III.

In one embodiment, among the above X₁₇-X₂₄, X₁₇ or X₁₈ is N, or X₁₇ and X₁₉ are N, or X₁₇ and X₂₀ are N.

In one embodiment, X₂₅-X₃₂ are all CH, or one or two of X₂₅-X₃₂ are N, and the others are CH; and the structure represented by Formula IV is connected to parent structure through any C atom of Formula IV.

In one embodiment, among the above X₂₅-X₃₂, one of X₂₅-X₂₈ is N, and one of X₂₉-X₃₂ is N.

In one embodiment, X₃₃-X₃₅ are all CH, or one, two or three of X₃₃-X₃₅ are N, and the others are CH; and the structure represented by Formula V is connected to parent structure through any C atom of Formula V.

In one embodiment, the structure represented by Formula II is selected from the group consisting of:

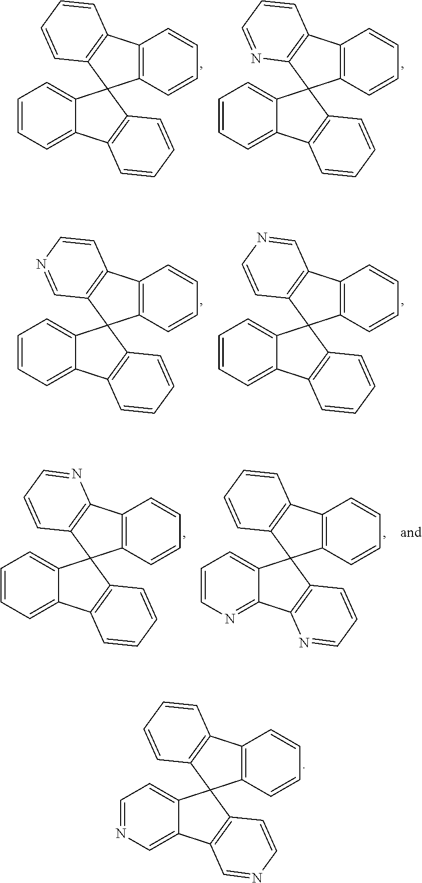

In one embodiment, the structure represented by Formula III is selected from the group consisting of:

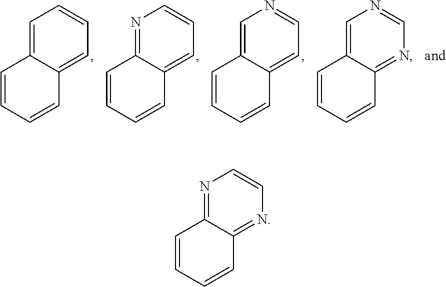

In one embodiment, Formula IV is selected from the group consisting of:

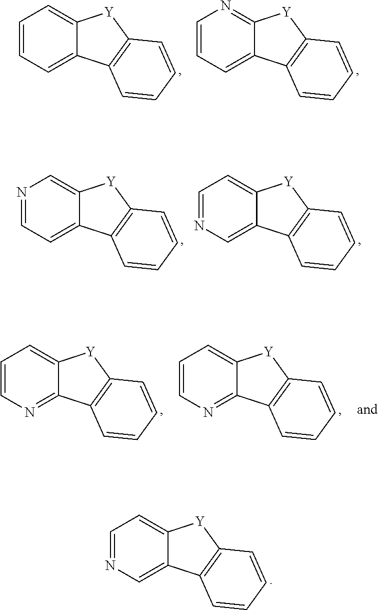

Y is selected from the group consisting of CH₂, C(CH₃)₂, O and S.

In one embodiment, the structure represented by Formula V is selected from the group consisting of:

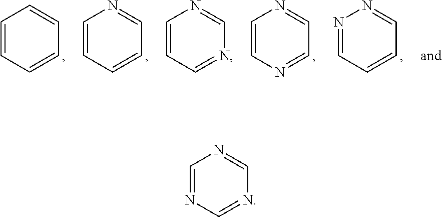

Ar₁-Ar₄ may be the same or different.

In one embodiment, at least one of Ar₁-Ar₄ is selected from the group consisting of structures represented by Formula II-Formula V, and the others are independently selected from the group consisting of substituted or unsubstituted C6-C30 aryl and substituted or unsubstituted C3-C30 heteroaryl.

In one embodiment, at least one of Ar₁-Ar₄ is selected from the group consisting of structures represented by Formula II-Formula V, and the others are independently selected from the group consisting of substituted or unsubstituted C6-C18 aryl and substituted or unsubstituted C3-C18 heteroaryl.

In one embodiment, at least one of Ar₁-Ar₄ is selected from the group consisting of structures represented by Formula II-Formula V, and the others are independently selected from the group consisting of substituted or unsubstituted C6-C12 aryl and substituted or unsubstituted C3-C12 heteroaryl.

In one embodiment, the C6-C30 aryl is selected from the group consisting of phenyl and a group formed by connecting 2 to 3 phenyl through a single bond.

In one embodiment, the C6-C30 aryl is selected from the group consisting of phenyl, biphenyl and terphenyl.

In one embodiment, the above C6-C30 aryl is selected from the group consisting of phenyl and biphenyl.

In one embodiment, the C3-C30 heteroaryl is selected from the group consisting of five-membered or six-membered monocyclic heteroaryl, fused-ring heteroaryl formed by a fusion of 1 or 2 five-membered or six-membered monocyclic heteroaryl groups and 1 or 2 phenyl groups, and fused-ring heteroaryl formed by a fusion of 2 or 3 five-membered or six-membered monocyclic heteroaryl groups.

The heteroatom of the above heteroaryl is selected from the group consisting of N, O, S, and a combination thereof.

In one embodiment, the C3-C30 heteroaryl is selected from the group consisting of pyrrolyl, pyridyl, pyrazinyl, pyrimidinyl, triazinyl, quinolyl, isoquinolyl, quinoxalinyl and quinazolinyl.

In one embodiment, one of Ar₁-Ar₄ is selected from the group consisting of structures represented by Formula II-Formula IV, and the others have the structure represented by Formula V.

In one embodiment, all of Ar₁-Ar₄ have the structure represented by Formula V.

In one embodiment, two or three of Ar₁-Ar₄ have the structure represented by Formula III, and the others have the structure represented by Formula V.

In one embodiment, two of Ar₁-Ar₄ have the structure represented by Formula III, and Ar₁ and Ar₃ are the structure represented by Formula III, or Ar₂ and Ar₄ are the structure represented by Formula III.

In one embodiment, the compounds with low refractive index do not contain a conjugated structure with three or more benzene rings, such as phenanthrene and pyrene. Test results show that the introduction of a conjugated structure with three or more benzene rings, especially four or more benzene rings, will greatly increase the refractive index of the compounds.

In one embodiment, the compounds with low refractive index of the present disclosure is selected from the group consisting of:

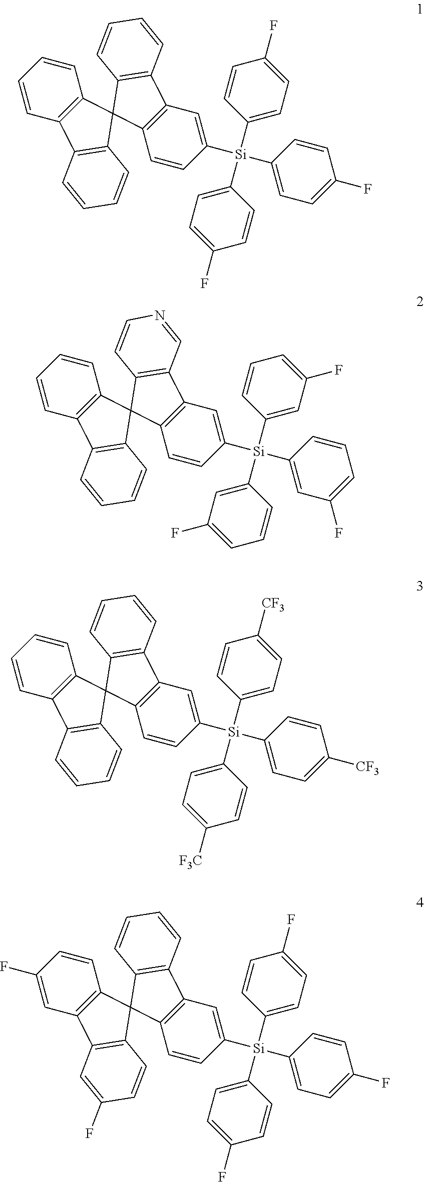 [SMILES: Fc1ccc([Si](c2ccc(F)cc2)(c2ccc(F)cc2)c2ccc3c(c2)-c2ccccc2C32c3ccccc3-c3ccccc32)cc1 ; Fc1cccc([Si](c2cccc(F)c2)(c2cccc(F)c2)c2ccc3c(c2)-c2cnccc2C32c3ccccc3-c3ccccc32)c1 ; FC(F)(F)c1ccc([Si](c2ccc(C(F)(F)F)cc2)(c2ccc(C(F)(F)F)cc2)c2ccc3c(c2)-c2ccccc2C32c3ccccc3-c3ccccc32)cc1 ; Fc1ccc([Si](c2ccc(F)cc2)(c2ccc(F)cc2)c2ccc3c(c2)-c2ccccc2C32c3ccc(F)cc3-c3cc(F)ccc32)cc1]

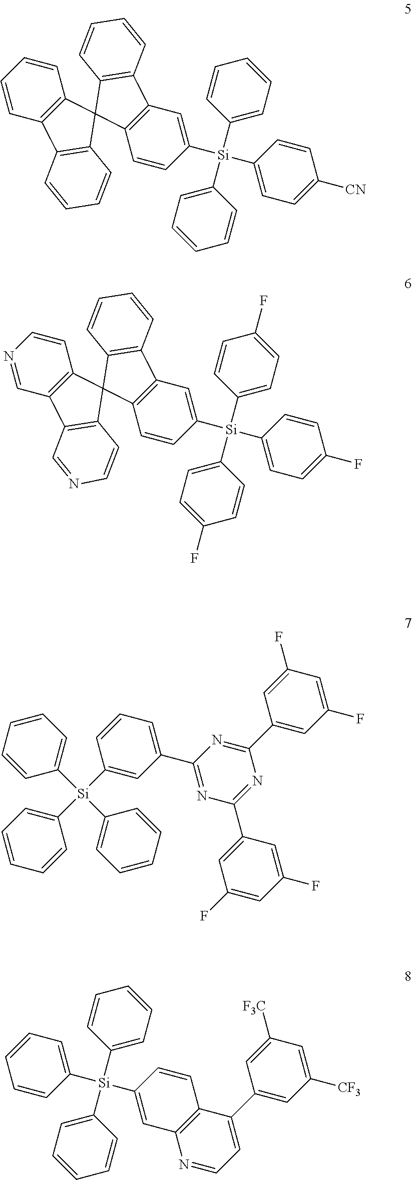 [SMILES: N#Cc1ccc([Si](c2ccccc2)(c2ccccc2)c2ccc3c(c2)-c2ccccc2C32c3ccccc3-c3ccccc32)cc1 ; Fc1ccc([Si](c2ccc(F)cc2)(c2ccc(F)cc2)c2ccc3c(c2)-c2ccccc2C32c3ccncc3-c3cnccc32)cc1 ; Fc1cc(F)cc(-c2nc(-c3cc(F)cc(F)c3)nc(-c3cccc([Si](c4ccccc4)(c4ccccc4)c4ccccc4)c3)n2)c1 ; FC(F)(F)c1cc(-c2ccnc3cc([Si](c4ccccc4)(c4ccccc4)c4ccccc4)ccc23)cc(C(F)(F)F)c1]

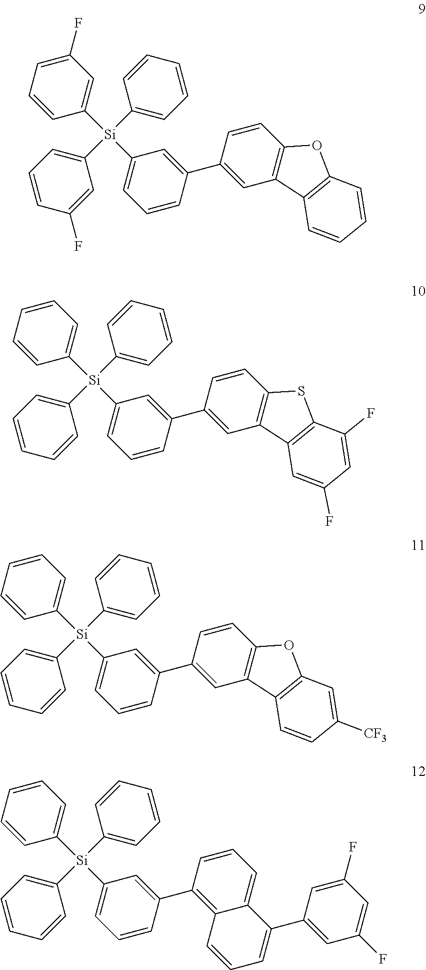 [SMILES: Fc1cccc([Si](c2ccccc2)(c2cccc(F)c2)c2cccc(-c3ccc4oc5ccccc5c4c3)c2)c1 ; Fc1cc(F)c2sc3ccc(-c4cccc([Si](c5ccccc5)(c5ccccc5)c5ccccc5)c4)cc3c2c1 ; FC(F)(F)c1ccc2c(c1)oc1ccc(-c3cccc([Si](c4ccccc4)(c4ccccc4)c4ccccc4)c3)cc12 ; Fc1cc(F)cc(-c2cccc3c(-c4cccc([Si](c5ccccc5)(c5ccccc5)c5ccccc5)c4)cccc23)c1]

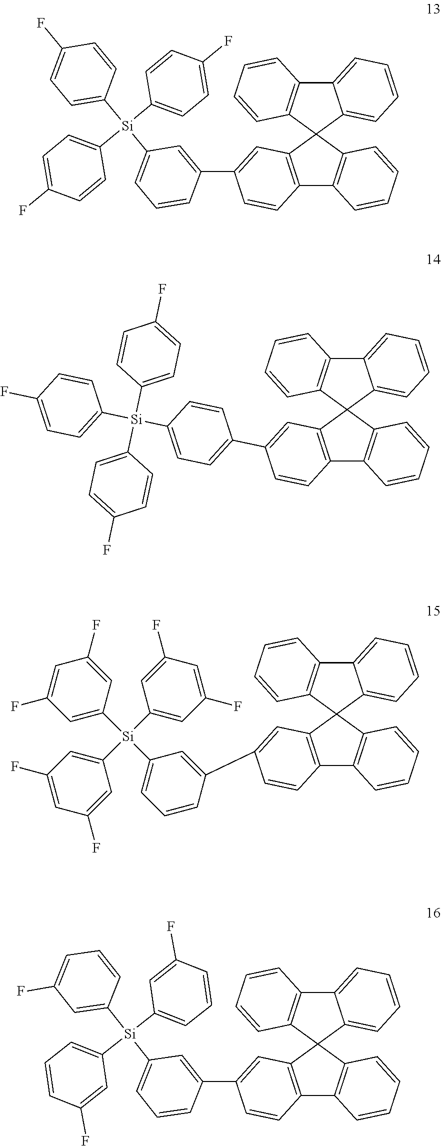 [SMILES: Fc1ccc([Si](c2ccc(F)cc2)(c2ccc(F)cc2)c2cccc(-c3ccc4c(c3)C3(c5ccccc5-c5ccccc53)c3ccccc3-4)c2)cc1 ; Fc1ccc([Si](c2ccc(F)cc2)(c2ccc(F)cc2)c2ccc(-c3ccc4c(c3)C3(c5ccccc5-c5ccccc53)c3ccccc3-4)cc2)cc1 ; Fc1cc(F)cc([Si](c2cc(F)cc(F)c2)(c2cc(F)cc(F)c2)c2cccc(-c3ccc4c(c3)C3(c5ccccc5-c5ccccc53)c3ccccc3-4)c2)c1 ; Fc1cccc([Si](c2cccc(F)c2)(c2cccc(F)c2)c2cccc(-c3ccc4c(c3)C3(c5ccccc5-c5ccccc53)c3ccccc3-4)c2)c1]

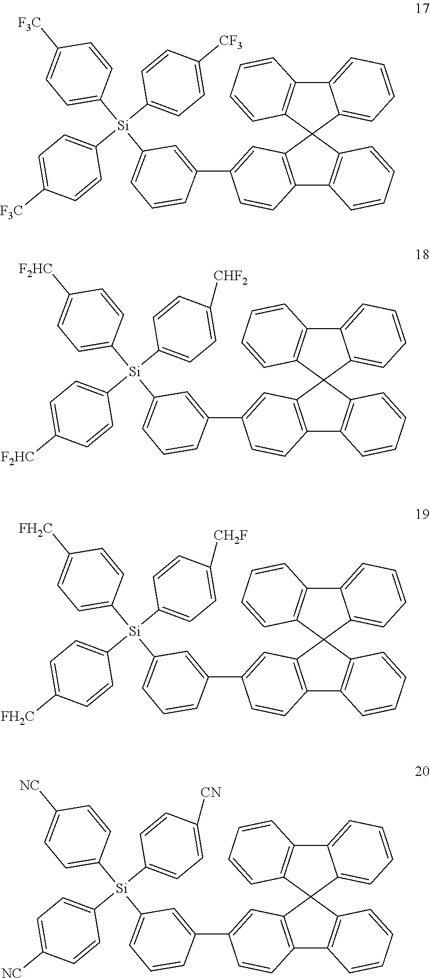

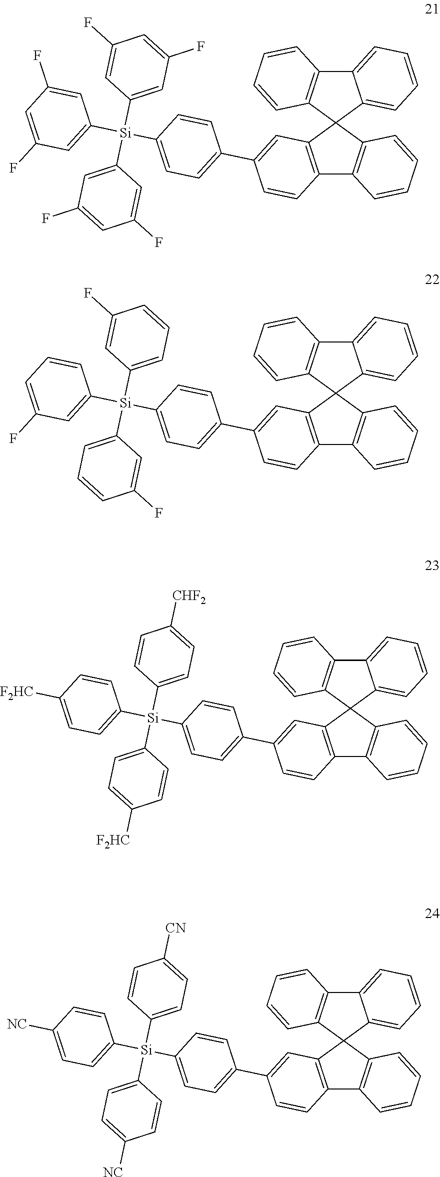 [SMILES: Fc1cc(F)cc([Si](c2ccc(-c3ccc4c(c3)C3(c5ccccc5-c5ccccc53)c3ccccc3-4)cc2)(c2cc(F)cc(F)c2)c2cc(F)cc(F)c2)c1 ; Fc1cccc([Si](c2ccc(-c3ccc4c(c3)C3(c5ccccc5-c5ccccc53)c3ccccc3-4)cc2)(c2cccc(F)c2)c2cccc(F)c2)c1 ; FC(F)c1ccc([Si](c2ccc(-c3ccc4c(c3)C3(c5ccccc5-c5ccccc53)c3ccccc3-4)cc2)(c2ccc(C(F)F)cc2)c2ccc(C(F)F)cc2)cc1 ; N#Cc1ccc([Si](c2ccc(C#N)cc2)(c2ccc(C#N)cc2)c2ccc(-c3ccc4c(c3)C3(c5ccccc5-c5ccccc53)c3ccccc3-4)cc2)cc1]

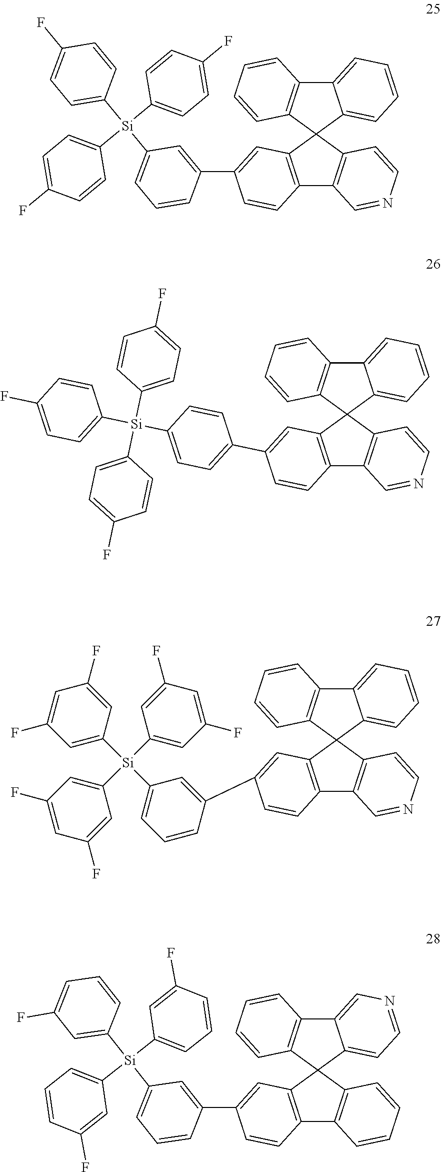 [SMILES: Fc1ccc([Si](c2ccc(F)cc2)(c2ccc(F)cc2)c2cccc(-c3ccc4c(c3)C3(c5ccccc5-c5ccccc53)c3ccncc3-4)c2)cc1 ; Fc1ccc([Si](c2ccc(F)cc2)(c2ccc(F)cc2)c2ccc(-c3ccc4c(c3)C3(c5ccccc5-c5ccccc53)c3ccncc3-4)cc2)cc1 ; Fc1cc(F)cc([Si](c2cc(F)cc(F)c2)(c2cc(F)cc(F)c2)c2cccc(-c3ccc4c(c3)C3(c5ccccc5-c5ccccc53)c3ccncc3-4)c2)c1 ; Fc1cccc([Si](c2cccc(F)c2)(c2cccc(F)c2)c2cccc(-c3ccc4c(c3)C3(c5ccccc5-c5cnccc53)c3ccccc3-4)c2)c1]

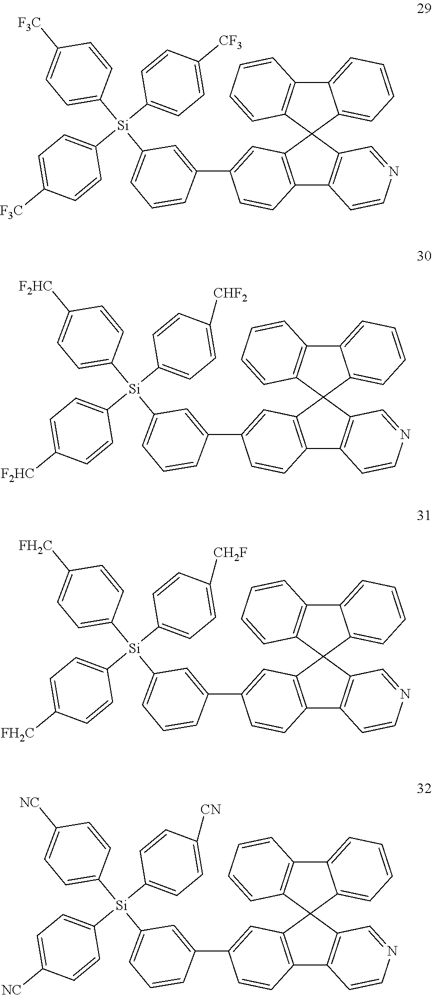

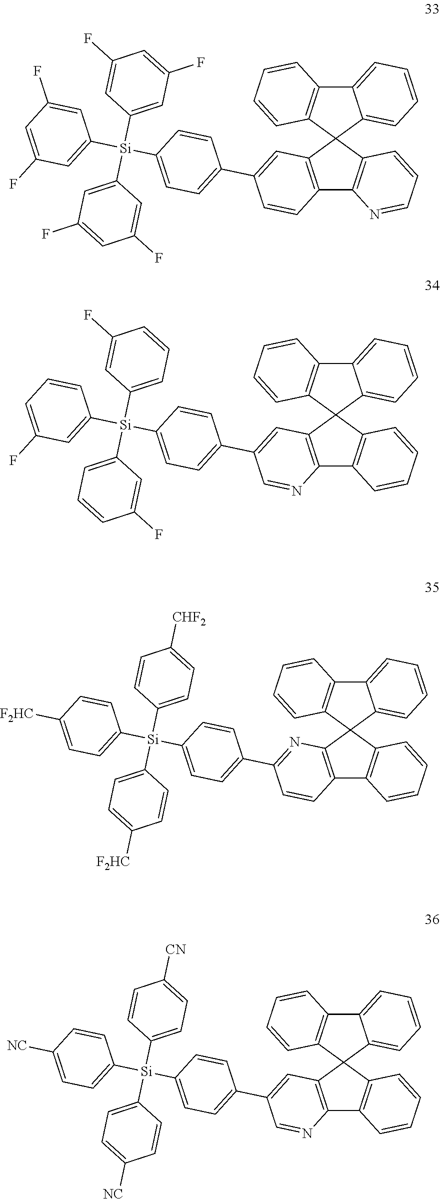 [SMILES: Fc1cc(F)cc([Si](c2ccc(-c3ccc4c(c3)C3(c5ccccc5-c5ccccc53)c3cccnc3-4)cc2)(c2cc(F)cc(F)c2)c2cc(F)cc(F)c2)c1 ; Fc1cccc([Si](c2ccc(-c3cnc4c(c3)C3(c5ccccc5-c5ccccc53)c3ccccc3-4)cc2)(c2cccc(F)c2)c2cccc(F)c2)c1 ; FC(F)c1ccc([Si](c2ccc(-c3ccc4c(n3)C3(c5ccccc5-c5ccccc53)c3ccccc3-4)cc2)(c2ccc(C(F)F)cc2)c2ccc(C(F)F)cc2)cc1 ; N#Cc1ccc([Si](c2ccc(C#N)cc2)(c2ccc(C#N)cc2)c2ccc(-c3cnc4c(c3)C3(c5ccccc5-c5ccccc53)c3ccccc3-4)cc2)cc1]

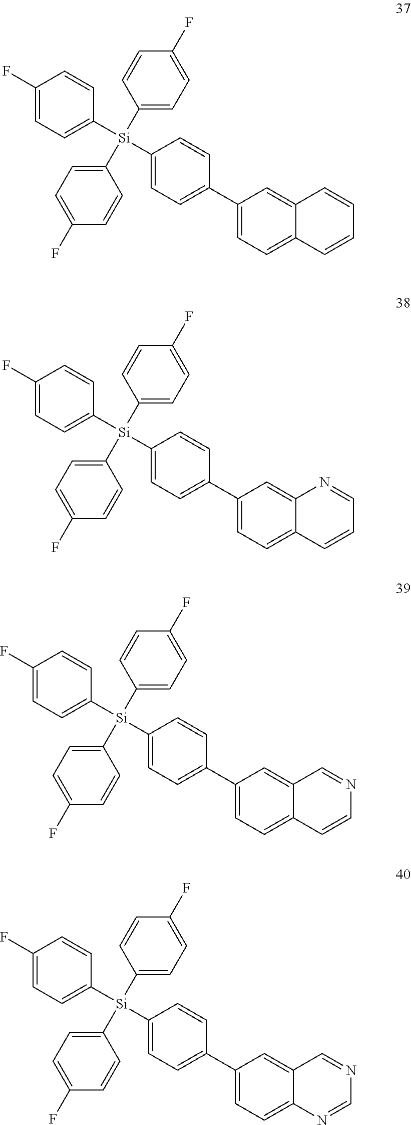 [SMILES: Fc1ccc([Si](c2ccc(F)cc2)(c2ccc(F)cc2)c2ccc(-c3ccc4ccccc4c3)cc2)cc1 ; Fc1ccc([Si](c2ccc(F)cc2)(c2ccc(F)cc2)c2ccc(-c3ccc4cccnc4c3)cc2)cc1 ; Fc1ccc([Si](c2ccc(F)cc2)(c2ccc(F)cc2)c2ccc(-c3ccc4ccncc4c3)cc2)cc1 ; Fc1ccc([Si](c2ccc(F)cc2)(c2ccc(F)cc2)c2ccc(-c3ccc4ncncc4c3)cc2)cc1]

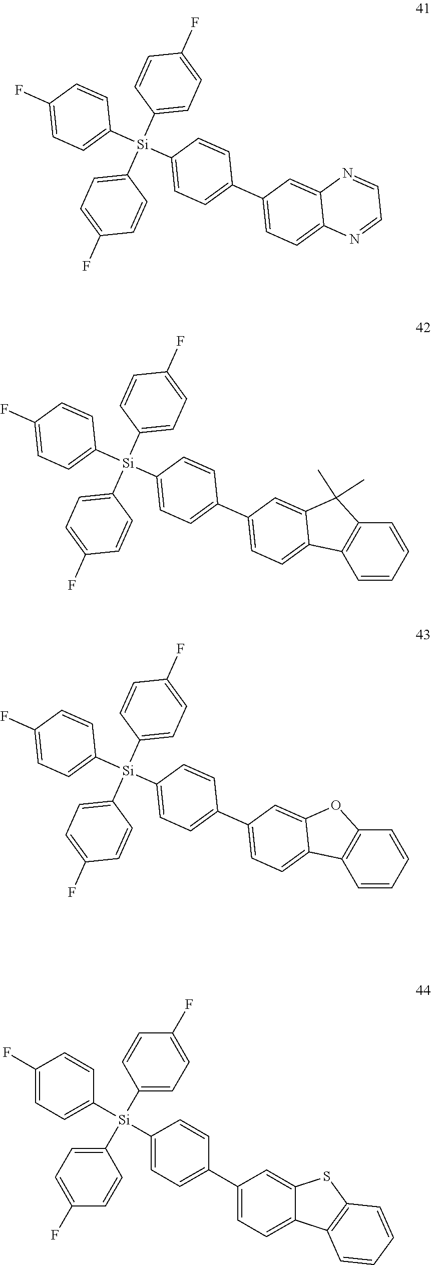 [SMILES: Fc1ccc([Si](c2ccc(F)cc2)(c2ccc(F)cc2)c2ccc(-c3ccc4nccnc4c3)cc2)cc1 ; CC1(C)c2ccccc2-c2ccc(-c3ccc([Si](c4ccc(F)cc4)(c4ccc(F)cc4)c4ccc(F)cc4)cc3)cc21 ; Fc1ccc([Si](c2ccc(F)cc2)(c2ccc(F)cc2)c2ccc(-c3ccc4c(c3)oc3ccccc34)cc2)cc1 ; Fc1ccc([Si](c2ccc(F)cc2)(c2ccc(F)cc2)c2ccc(-c3ccc4c(c3)sc3ccccc34)cc2)cc1]

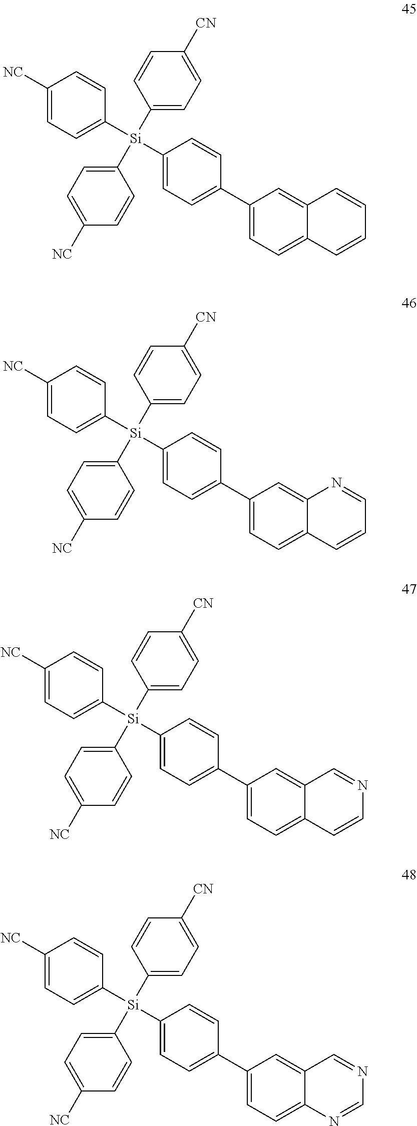 [SMILES: N#Cc1ccc([Si](c2ccc(C#N)cc2)(c2ccc(C#N)cc2)c2ccc(-c3ccc4ccccc4c3)cc2)cc1 ; N#Cc1ccc([Si](c2ccc(C#N)cc2)(c2ccc(C#N)cc2)c2ccc(-c3ccc4cccnc4c3)cc2)cc1 ; N#Cc1ccc([Si](c2ccc(C#N)cc2)(c2ccc(C#N)cc2)c2ccc(-c3ccc4ccncc4c3)cc2)cc1 ; N#Cc1ccc([Si](c2ccc(C#N)cc2)(c2ccc(C#N)cc2)c2ccc(-c3ccc4ncncc4c3)cc2)cc1]

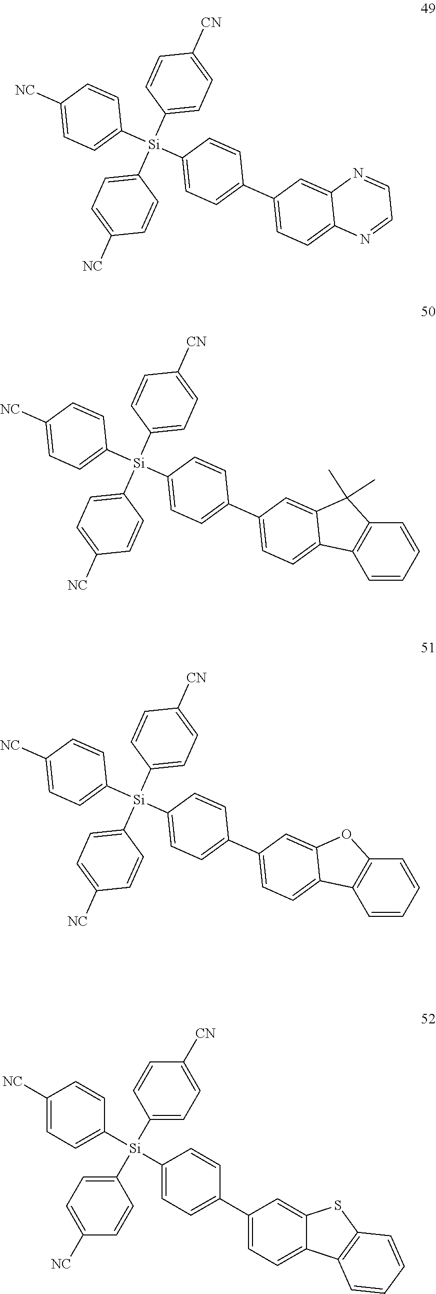 [SMILES: N#Cc1ccc([Si](c2ccc(C#N)cc2)(c2ccc(C#N)cc2)c2ccc(-c3ccc4nccnc4c3)cc2)cc1 ; CC1(C)c2ccccc2-c2ccc(-c3ccc([Si](c4ccc(C#N)cc4)(c4ccc(C#N)cc4)c4ccc(C#N)cc4)cc3)cc21 ; N#Cc1ccc([Si](c2ccc(C#N)cc2)(c2ccc(C#N)cc2)c2ccc(-c3ccc4c(c3)oc3ccccc34)cc2)cc1 ; N#Cc1ccc([Si](c2ccc(C#N)cc2)(c2ccc(C#N)cc2)c2ccc(-c3ccc4c(c3)sc3ccccc34)cc2)cc1]

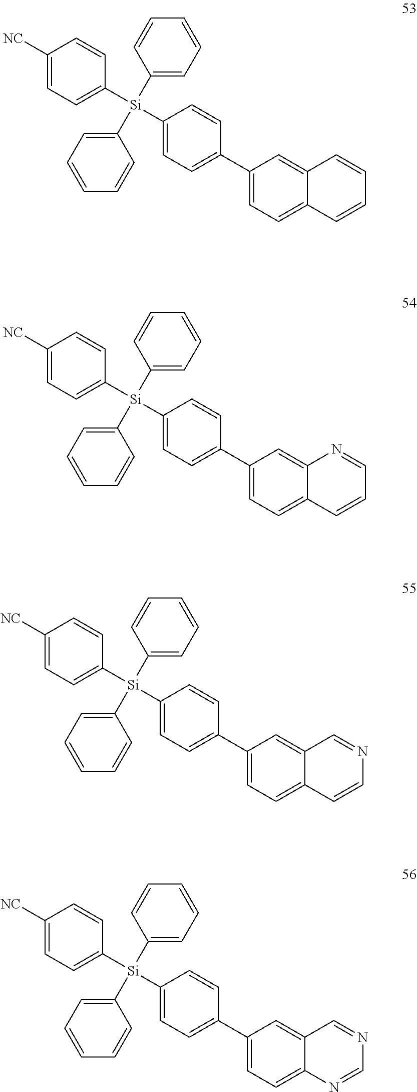 [SMILES: N#Cc1ccc([Si](c2ccccc2)(c2ccccc2)c2ccc(-c3ccc4ccccc4c3)cc2)cc1 ; N#Cc1ccc([Si](c2ccccc2)(c2ccccc2)c2ccc(-c3ccc4cccnc4c3)cc2)cc1 ; N#Cc1ccc([Si](c2ccccc2)(c2ccccc2)c2ccc(-c3ccc4ccncc4c3)cc2)cc1 ; N#Cc1ccc([Si](c2ccccc2)(c2ccccc2)c2ccc(-c3ccc4ncncc4c3)cc2)cc1]

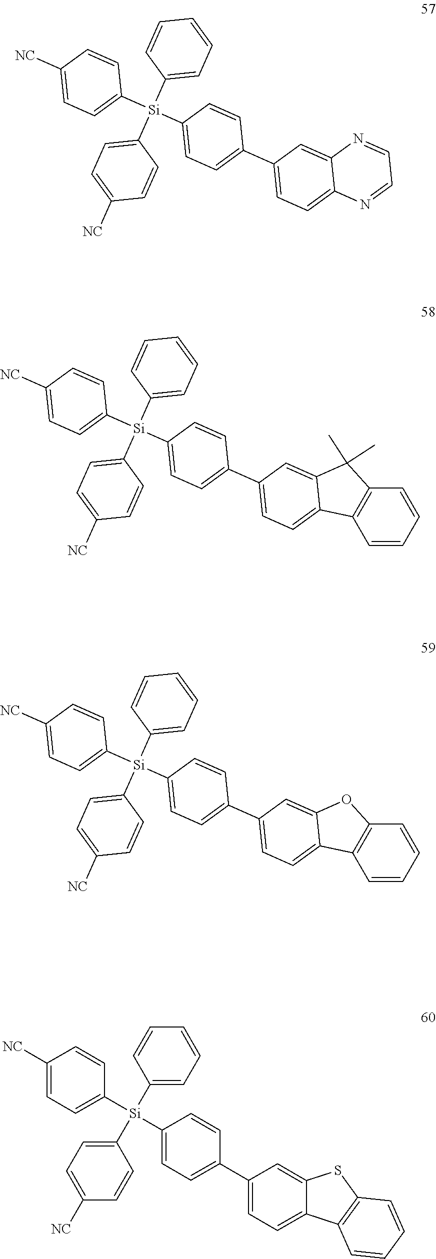 [SMILES: N#Cc1ccc([Si](c2ccccc2)(c2ccc(C#N)cc2)c2ccc(-c3ccc4nccnc4c3)cc2)cc1 ; CC1(C)c2ccccc2-c2ccc(-c3ccc([Si](c4ccccc4)(c4ccc(C#N)cc4)c4ccc(C#N)cc4)cc3)cc21 ; N#Cc1ccc([Si](c2ccccc2)(c2ccc(C#N)cc2)c2ccc(-c3ccc4c(c3)oc3ccccc34)cc2)cc1 ; N#Cc1ccc([Si](c2ccccc2)(c2ccc(C#N)cc2)c2ccc(-c3ccc4c(c3)sc3ccccc34)cc2)cc1]

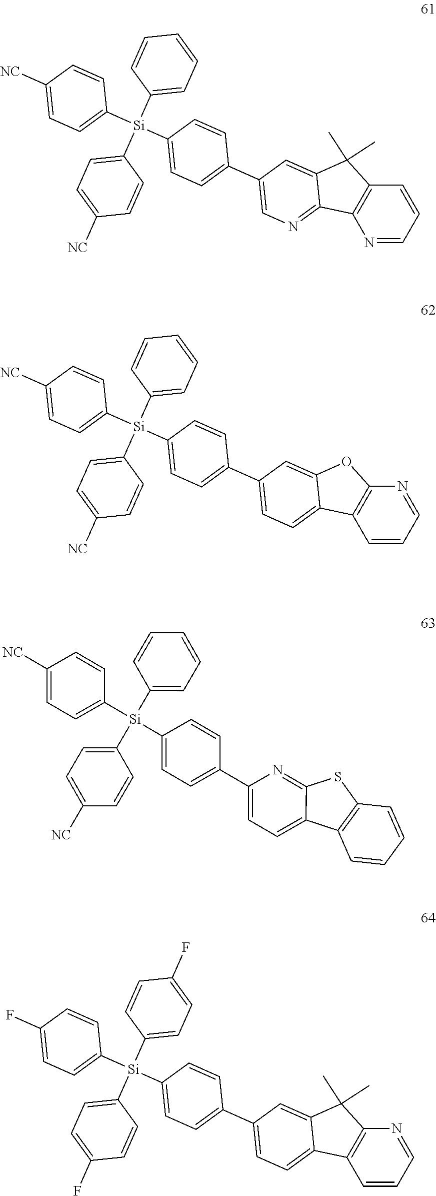 [SMILES: CC1(C)c2cccnc2-c2ncc(-c3ccc([Si](c4ccccc4)(c4ccc(C#N)cc4)c4ccc(C#N)cc4)cc3)cc21 ; N#Cc1ccc([Si](c2ccccc2)(c2ccc(C#N)cc2)c2ccc(-c3ccc4c(c3)oc3ncccc34)cc2)cc1 ; N#Cc1ccc([Si](c2ccccc2)(c2ccc(C#N)cc2)c2ccc(-c3ccc4c(n3)sc3ccccc34)cc2)cc1 ; CC1(C)c2cc(-c3ccc([Si](c4ccc(F)cc4)(c4ccc(F)cc4)c4ccc(F)cc4)cc3)ccc2-c2cccnc21]

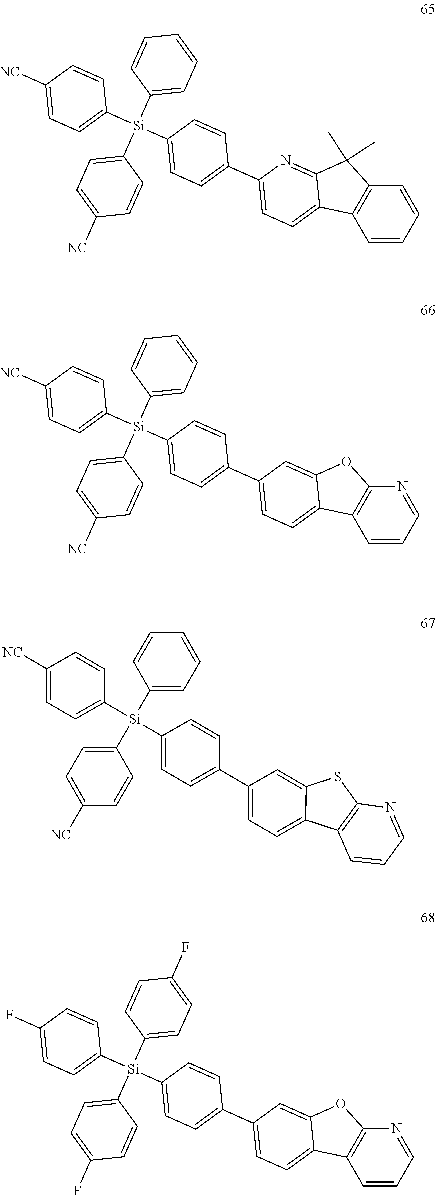 [SMILES: CC1(C)c2ccccc2-c2ccc(-c3ccc([Si](c4ccccc4)(c4ccc(C#N)cc4)c4ccc(C#N)cc4)cc3)nc21 ; N#Cc1ccc([Si](c2ccccc2)(c2ccc(C#N)cc2)c2ccc(-c3ccc4c(c3)oc3ncccc34)cc2)cc1 ; N#Cc1ccc([Si](c2ccccc2)(c2ccc(C#N)cc2)c2ccc(-c3ccc4c(c3)sc3ncccc34)cc2)cc1 ; Fc1ccc([Si](c2ccc(F)cc2)(c2ccc(F)cc2)c2ccc(-c3ccc4c(c3)oc3ncccc34)cc2)cc1]

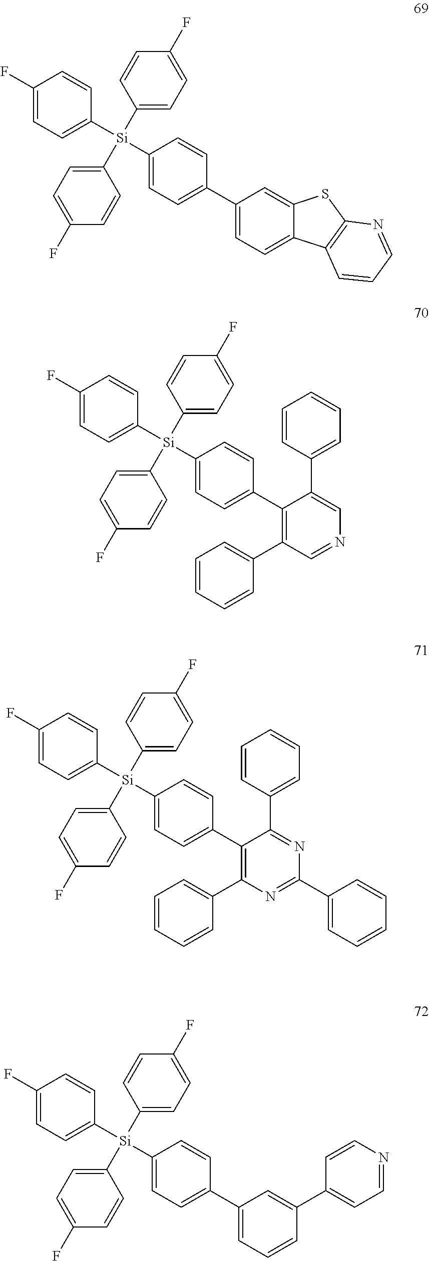 [SMILES: Fc1ccc([Si](c2ccc(F)cc2)(c2ccc(F)cc2)c2ccc(-c3ccc4c(c3)sc3ncccc34)cc2)cc1 ; Fc1ccc([Si](c2ccc(F)cc2)(c2ccc(F)cc2)c2ccc(-c3c(-c4ccccc4)cncc3-c3ccccc3)cc2)cc1 ; Fc1ccc([Si](c2ccc(F)cc2)(c2ccc(F)cc2)c2ccc(-c3c(-c4ccccc4)nc(-c4ccccc4)nc3-c3ccccc3)cc2)cc1 ; Fc1ccc([Si](c2ccc(F)cc2)(c2ccc(F)cc2)c2ccc(-c3cccc(-c4ccncc4)c3)cc2)cc1]

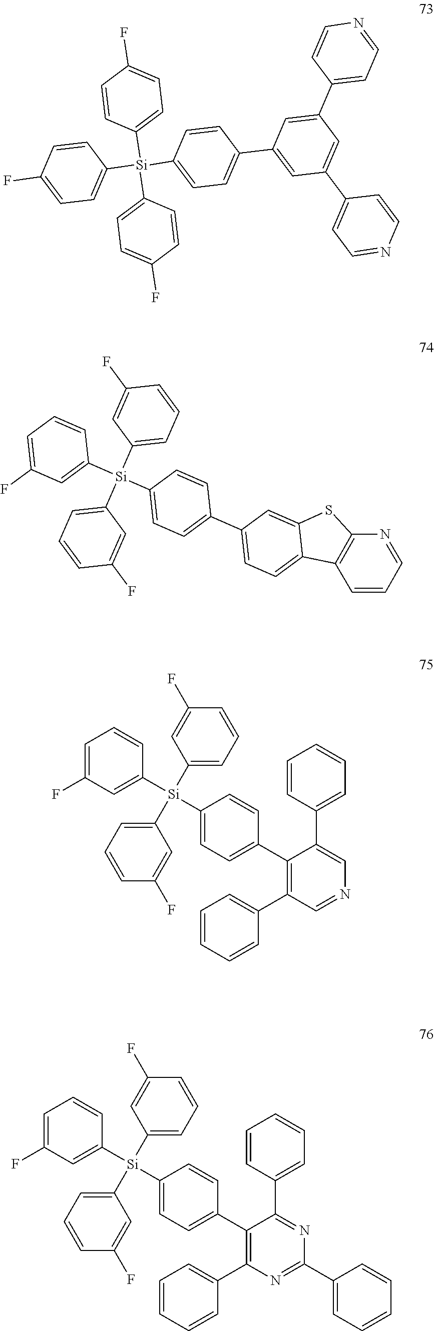 [SMILES: Fc1ccc([Si](c2ccc(F)cc2)(c2ccc(F)cc2)c2ccc(-c3cc(-c4ccncc4)cc(-c4ccncc4)c3)cc2)cc1 ; Fc1cccc([Si](c2ccc(-c3ccc4c(c3)sc3ncccc34)cc2)(c2cccc(F)c2)c2cccc(F)c2)c1 ; Fc1cccc([Si](c2ccc(-c3c(-c4ccccc4)cncc3-c3ccccc3)cc2)(c2cccc(F)c2)c2cccc(F)c2)c1 ; Fc1cccc([Si](c2ccc(-c3c(-c4ccccc4)nc(-c4ccccc4)nc3-c3ccccc3)cc2)(c2cccc(F)c2)c2cccc(F)c2)c1]

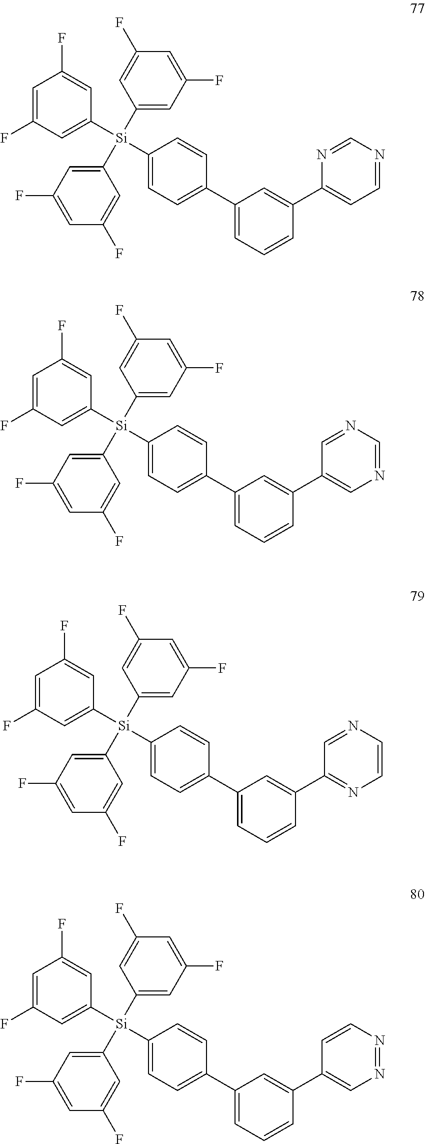 [SMILES: Fc1cc(F)cc([Si](c2ccc(-c3cccc(-c4ccncn4)c3)cc2)(c2cc(F)cc(F)c2)c2cc(F)cc(F)c2)c1 ; Fc1cc(F)cc([Si](c2ccc(-c3cccc(-c4cncnc4)c3)cc2)(c2cc(F)cc(F)c2)c2cc(F)cc(F)c2)c1 ; Fc1cc(F)cc([Si](c2ccc(-c3cccc(-c4cnccn4)c3)cc2)(c2cc(F)cc(F)c2)c2cc(F)cc(F)c2)c1 ; Fc1cc(F)cc([Si](c2ccc(-c3cccc(-c4ccnnc4)c3)cc2)(c2cc(F)cc(F)c2)c2cc(F)cc(F)c2)c1]

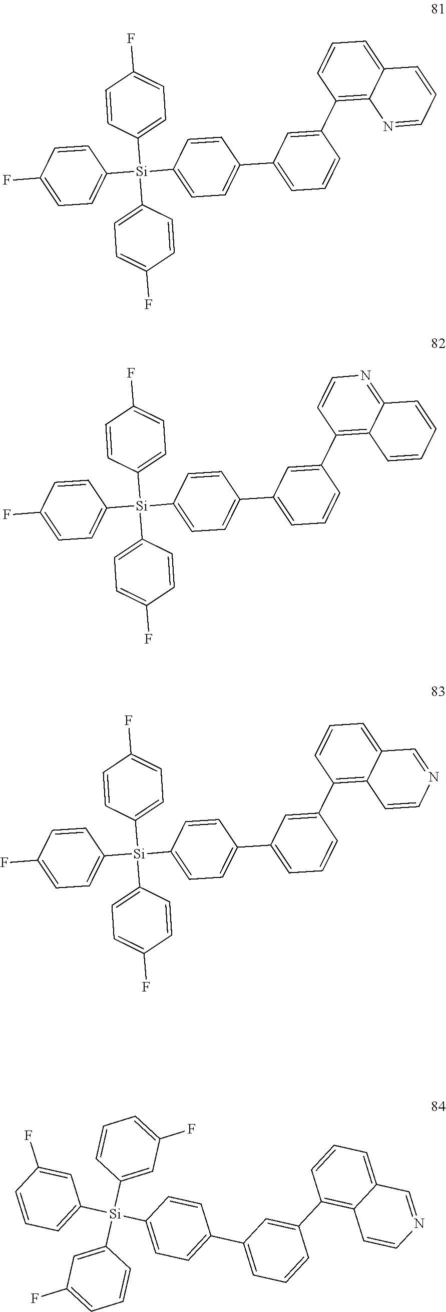 [SMILES: Fc1ccc([Si](c2ccc(F)cc2)(c2ccc(F)cc2)c2ccc(-c3cccc(-c4cccc5cccnc45)c3)cc2)cc1 ; Fc1ccc([Si](c2ccc(F)cc2)(c2ccc(F)cc2)c2ccc(-c3cccc(-c4ccnc5ccccc45)c3)cc2)cc1 ; Fc1ccc([Si](c2ccc(F)cc2)(c2ccc(F)cc2)c2ccc(-c3cccc(-c4cccc5cnccc45)c3)cc2)cc1 ; Fc1cccc([Si](c2ccc(-c3cccc(-c4cccc5cnccc45)c3)cc2)(c2cccc(F)c2)c2cccc(F)c2)c1]

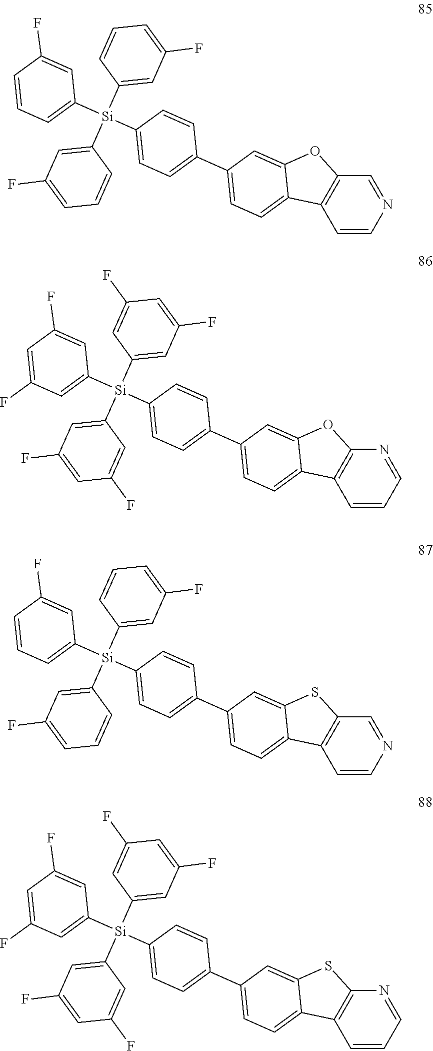 [SMILES: Fc1cccc([Si](c2ccc(-c3ccc4c(c3)oc3cnccc34)cc2)(c2cccc(F)c2)c2cccc(F)c2)c1 ; Fc1cc(F)cc([Si](c2ccc(-c3ccc4c(c3)oc3ncccc34)cc2)(c2cc(F)cc(F)c2)c2cc(F)cc(F)c2)c1 ; Fc1cccc([Si](c2ccc(-c3ccc4c(c3)sc3cnccc34)cc2)(c2cccc(F)c2)c2cccc(F)c2)c1 ; Fc1cc(F)cc([Si](c2ccc(-c3ccc4c(c3)sc3ncccc34)cc2)(c2cc(F)cc(F)c2)c2cc(F)cc(F)c2)c1]

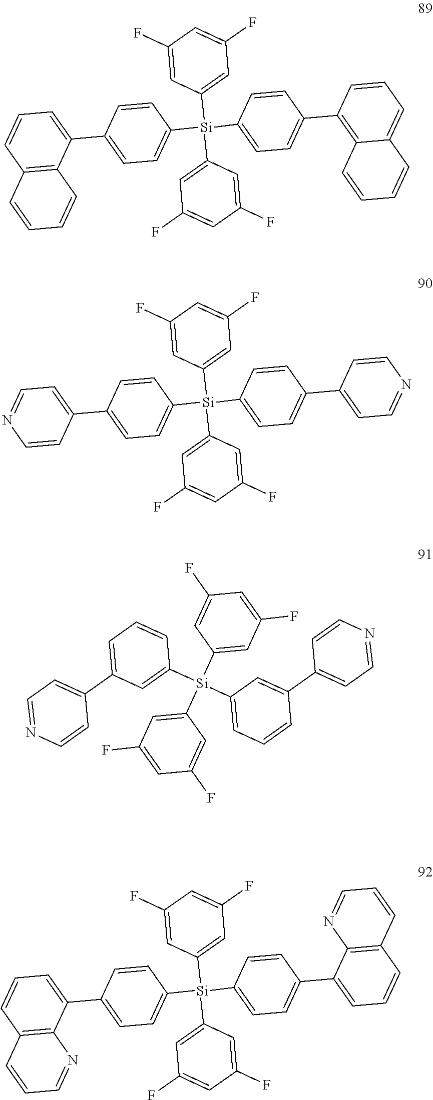 [SMILES: Fc1cc(F)cc([Si](c2ccc(-c3cccc4ccccc34)cc2)(c2ccc(-c3cccc4ccccc34)cc2)c2cc(F)cc(F)c2)c1 ; Fc1cc(F)cc([Si](c2ccc(-c3ccncc3)cc2)(c2ccc(-c3ccncc3)cc2)c2cc(F)cc(F)c2)c1 ; Fc1cc(F)cc([Si](c2cc(F)cc(F)c2)(c2cccc(-c3ccncc3)c2)c2cccc(-c3ccncc3)c2)c1 ; Fc1cc(F)cc([Si](c2ccc(-c3cccc4cccnc34)cc2)(c2ccc(-c3cccc4cccnc34)cc2)c2cc(F)cc(F)c2)c1]

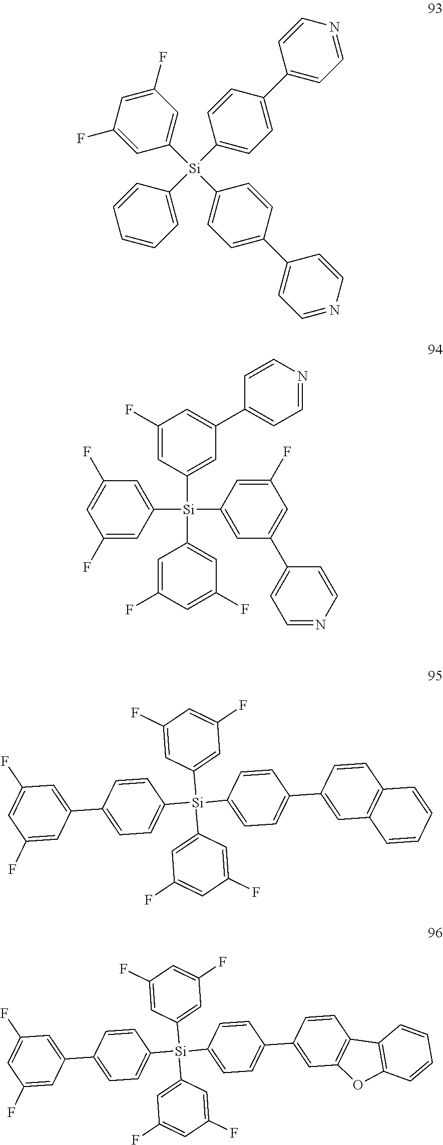 [SMILES: Fc1cc(F)cc([Si](c2ccccc2)(c2ccc(-c3ccncc3)cc2)c2ccc(-c3ccncc3)cc2)c1 ; Fc1cc(F)cc([Si](c2cc(F)cc(F)c2)(c2cc(F)cc(-c3ccncc3)c2)c2cc(F)cc(-c3ccncc3)c2)c1 ; Fc1cc(F)cc(-c2ccc([Si](c3ccc(-c4ccc5ccccc5c4)cc3)(c3cc(F)cc(F)c3)c3cc(F)cc(F)c3)cc2)c1 ; Fc1cc(F)cc(-c2ccc([Si](c3ccc(-c4ccc5c(c4)oc4ccccc45)cc3)(c3cc(F)cc(F)c3)c3cc(F)cc(F)c3)cc2)c1]

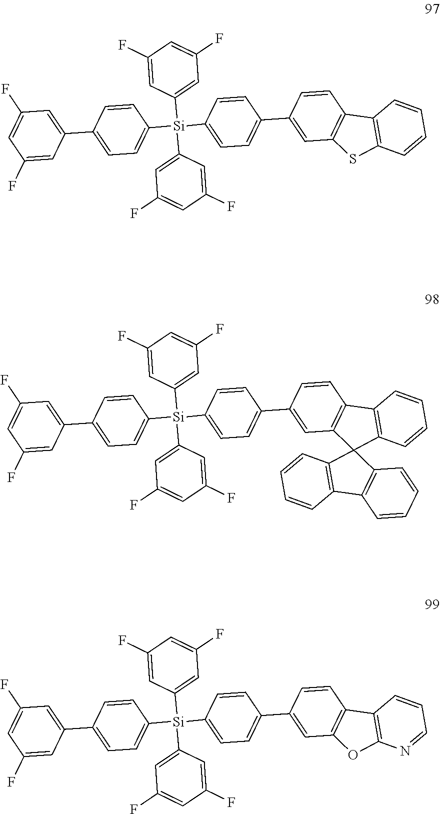 [SMILES: Fc1cc(F)cc(-c2ccc([Si](c3ccc(-c4ccc5c(c4)sc4ccccc45)cc3)(c3cc(F)cc(F)c3)c3cc(F)cc(F)c3)cc2)c1 ; Fc1cc(F)cc(-c2ccc([Si](c3ccc(-c4ccc5c(c4)C4(c6ccccc6-c6ccccc64)c4ccccc4-5)cc3)(c3cc(F)cc(F)c3)c3cc(F)cc(F)c3)cc2)c1 ; Fc1cc(F)cc(-c2ccc([Si](c3ccc(-c4ccc5c(c4)oc4ncccc45)cc3)(c3cc(F)cc(F)c3)c3cc(F)cc(F)c3)cc2)c1]

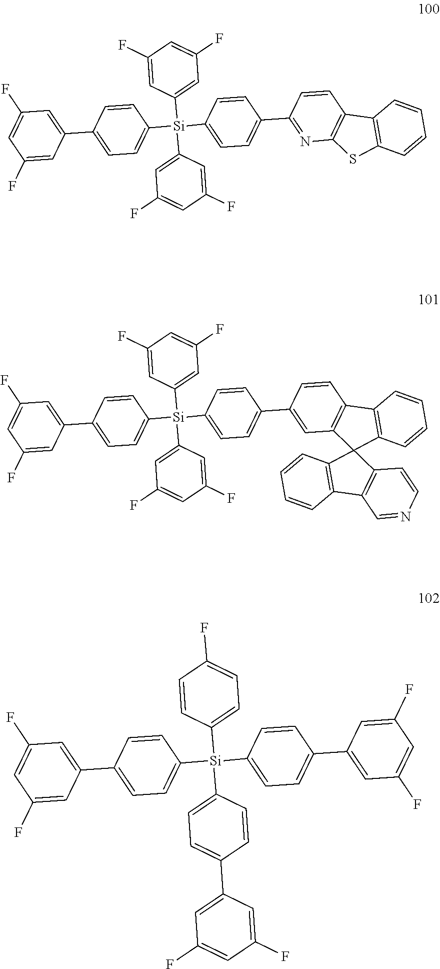 [SMILES: Fc1cc(F)cc(-c2ccc([Si](c3ccc(-c4ccc5c(n4)sc4ccccc45)cc3)(c3cc(F)cc(F)c3)c3cc(F)cc(F)c3)cc2)c1 ; Fc1cc(F)cc(-c2ccc([Si](c3ccc(-c4ccc5c(c4)C4(c6ccccc6-c6cnccc64)c4ccccc4-5)cc3)(c3cc(F)cc(F)c3)c3cc(F)cc(F)c3)cc2)c1 ; Fc1ccc([Si](c2ccc(-c3cc(F)cc(F)c3)cc2)(c2ccc(-c3cc(F)cc(F)c3)cc2)c2ccc(-c3cc(F)cc(F)c3)cc2)cc1]

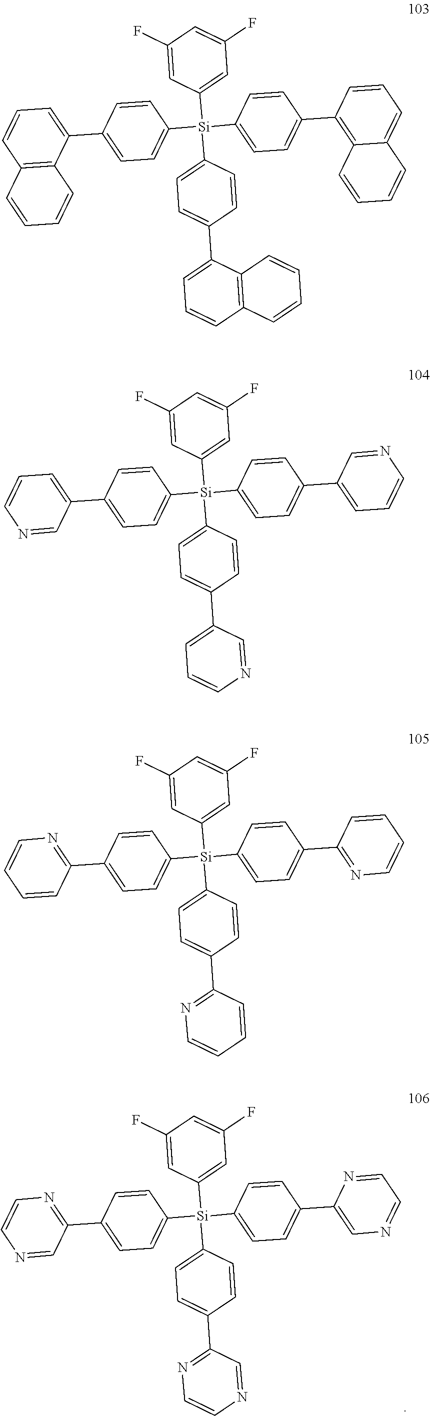 [SMILES: Fc1cc(F)cc([Si](c2ccc(-c3cccc4ccccc34)cc2)(c2ccc(-c3cccc4ccccc34)cc2)c2ccc(-c3cccc4ccccc34)cc2)c1 ; Fc1cc(F)cc([Si](c2ccc(-c3cccnc3)cc2)(c2ccc(-c3cccnc3)cc2)c2ccc(-c3cccnc3)cc2)c1 ; Fc1cc(F)cc([Si](c2ccc(-c3ccccn3)cc2)(c2ccc(-c3ccccn3)cc2)c2ccc(-c3ccccn3)cc2)c1 ; Fc1cc(F)cc([Si](c2ccc(-c3cnccn3)cc2)(c2ccc(-c3cnccn3)cc2)c2ccc(-c3cnccn3)cc2)c1]

The present disclosure provides an organic light-emitting diode, which comprises a capping layer (CPL), and the capping layer comprises at least one of the compounds with low refractive index.

The present disclosure provides a display panel comprising an organic light-emitting diode, and the organic light-emitting diode comprises an anode, a cathode arranged oppositely, a capping layer located on a side of the cathode away from the anode, and an organic layer provided between the anode and the cathode; and the capping layer comprises at least one of the compounds with low refractive index.

In one embodiment, the capping layer is a double-layered capping layer, and the double-layered capping layer comprises a low-refractive capping layer and a high-refractive capping layer, the low-refractive capping layer comprises at least one of the above compounds with low refractive index, the high-refractive capping layer comprises a compound with high refractive index with an N value greater than 1.9.

In one embodiment, the compound with high refractive index has the following structure:

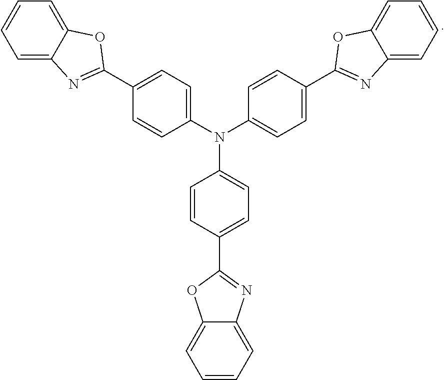 [SMILES: c1ccc2oc(-c3ccc(N(c4ccc(-c5nc6ccccc6o5)cc4)c4ccc(-c5nc6ccccc6o5)cc4)cc3)nc2c1]

In one embodiment, the capping layer is provided on the surface of a side of the cathode away from the anode.

In one embodiment, the organic layer located between the anode and the cathode comprises a first hole-transporting layer, a second hole-transporting layer, an electron-blocking layer, a light-emitting layer, a first electron-transporting layer, and a second electron-transporting layer.

The organic light-emitting diode provided by the present disclosure may be an organic light-emitting diode well known in the art. In one embodiment in the present disclosure, the organic light-emitting diode comprises a substrate, an ITO anode, a first hole-transporting layer, a second hole-transporting layer, an electron-blocking layer, a light-emitting layer, a first electron-transporting layer, a second electron-transporting layer, a cathode (magnesium-silver electrode, mass ratio of magnesium to silver being 1:9) and a capping layer (CPL) in order.

In one embodiment, the anode materials of the organic light-emitting diode may be metals, such as copper, gold, silver, iron, chromium, nickel, manganese, palladium, platinum and their alloys; metal oxides, such as indium oxide, zinc oxide, indium tin oxide (ITO), indium, and zinc oxide (IZO); conductive polymers, such as polyaniline, polypyrrole, and poly(3-methylthiophene), materials conducive to hole injection and known to be suitable for anodes, or a combination thereof.

In one embodiment, the cathode materials of the organic light-emitting diode may metals, such as aluminum, magnesium, silver, indium, tin, titanium, and their alloys; multi-layer metal materials, such as LiF/Al, LiO₂/Al, and BaF₂/Al; materials conducive to electron injection and known to be suitable for cathodes, or a combination thereof.

In one embodiment, for the organic optoelectronic device, such as the organic light-emitting diode, the organic thin film layer comprises at least one light-emitting layer (EML), and may also comprise other functional layers, including a hole injection layer (HIL), hole-transporting layer (HTL), electron-blocking layer (EBL), hole-blocking layer (HBL), electron-transporting layer (ETL), and electron injection layer (EIL).

In one embodiment, the organic light-emitting diode is prepared by:
forming an anode on a transparent or opaque smooth substrate, forming an organic thin layer on the anode, and forming a cathode on the organic thin layer.

In one embodiment, the formation of the organic thin layer is carried out by known film forming methods such as evaporation, sputtering, spin coating, dipping, and ion plating.

The present disclosure provides a display device comprising the above display panel.

In the present disclosure, organic light-emitting diode (OLED devices) can be used in display devices, and the organic light-emitting display device can be a mobile phone display screen, a computer display screen, a TV display screen, a smart watch display screen, a smart car display panel, a VR or AR helmet display screen, display screens for various smart devices, etc.

The following are illustrative examples of some low refractive index compounds of the present disclosure.

### Example 1

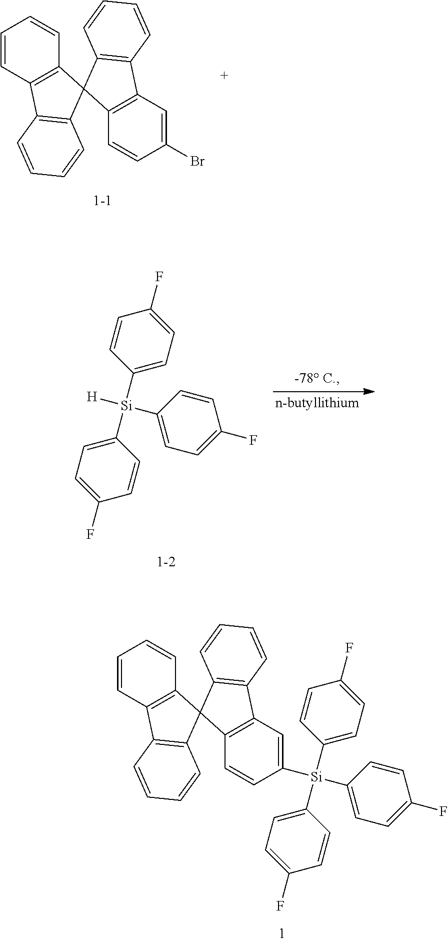 [SMILES: Brc1ccc2c(c1)-c1ccccc1C21c2ccccc2-c2ccccc21 ; Fc1ccc([SiH](c2ccc(F)cc2)c2ccc(F)cc2)cc1 ; Fc1ccc([Si](c2ccc(F)cc2)(c2ccc(F)cc2)c2ccc3c(c2)-c2ccccc2C32c3ccccc3-c3ccccc32)cc1]

(1) Compound 1-1 (3-bromo-9,9-spirobifluorene, 75 mmol) was dissolved in anhydrous THE, cooled to −78° C., slowly added dropwise with 150 mmol n-butyllithium. The reaction system was naturally warmed to room temperature for reaction overnight. The next day, the reaction solution was added with compound 1-2 (1,1,1,-tri (4-fluorophenyl) silane, 100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction and extraction was performed three times. Then the solvent was removed from the organic layer by using a rotary evaporator and the organic layer was subjected to column chromatography, crude product 1 was obtained.

The structure of target product 1 was determined by MALDI-TOF MS (MALDI coupled to time-of-flight mass spectrometry), MALDI-TOF MS (m/z): C₄₃H₂₇F₃Si. The theoretical value is 628.8, and the measured value is 628.2.

Elemental analysis: theoretical value C: 77.71, H: 4.37; measured value C: 77.70, H: 4.36.

### Example 2

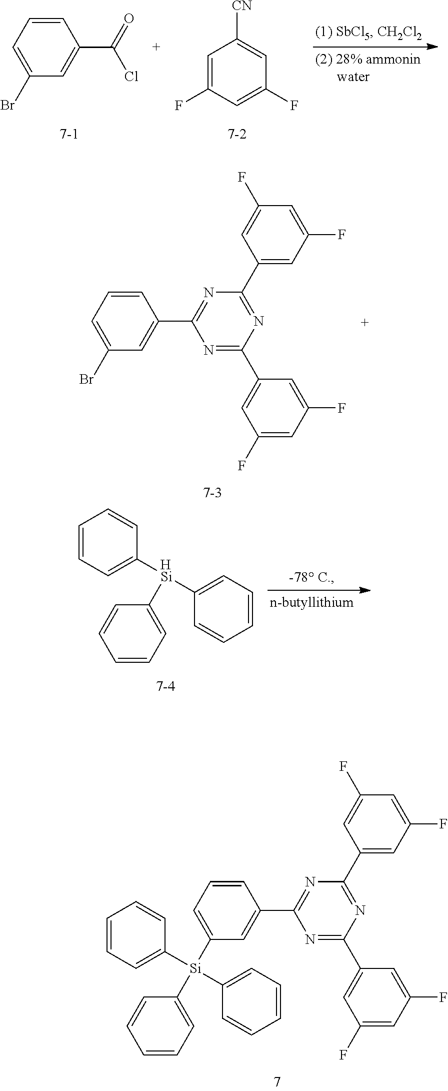

(1) Compound 7-1 (11 mmol) and compound 7-2 (22 mmol) were added to 15 mL of dichloromethane solution, mixed in a 50 mL flask, cooled to 0-5° C., stirred for 30 min, added with SbCl₅ (11 mmol), reacted at room temperature for 1 h, and then refluxed overnight. The reaction solution was cooled to room temperature, and the obtained yellow solid was washed with dichloromethane. Then 75 ml of 28% ammonia water was slowly added to the yellow solid, cooled to 0-5° C., stirred for 30 min, and then reacted at room temperature for 3 h. The resultant solid was washed with water, added with 30 ml of N,N-dimethylformamide, reacted at 155° C. for 30 min, then slowly added with saturated MgSO₄ aqueous solution and ethyl acetate for extraction, and extraction was performed three times. Then the solvent was removed from the organic layer by using a rotary evaporator and the organic layer was subjected to column chromatography, crude product 7-3 was obtained.

The structure of target product 7-3 was determined by MALDI-TOF MS (MALDI coupled to time-of-flight mass spectrometry), MALDI-TOF MS (m/z): C₂₁H₁₀BrF₄N₃. The theoretical value is 460.2, and the measured value is 459.0.

(2) Compound 7-3 (75 mmol) was dissolved in anhydrous THF, cooled to −78° C., slowly added dropwise with 150 mmol n-butyllithium, and then naturally warmed to room temperature for reaction overnight. The next day, the reaction solution was added with compound 7-4 (100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction, and extraction was performed three times. Then the solvent was removed from the organic layer by using a rotary evaporator and the organic layer was subjected to column chromatography, crude product 7 was obtained.

The structure of target product 7 was determined by MALDI-TOF MS (MALDI coupled to time-of-flight mass spectrometry), MALDI-TOF MS (m/z): C₃₉H₂₅F₄N₃Si. The theoretical value is 639.7, and the measured value is 639.2.

Elemental analysis: theoretical value C: 73.22, H: 3.94; measured value C: 73.21, H: 6.58.

### Example 3

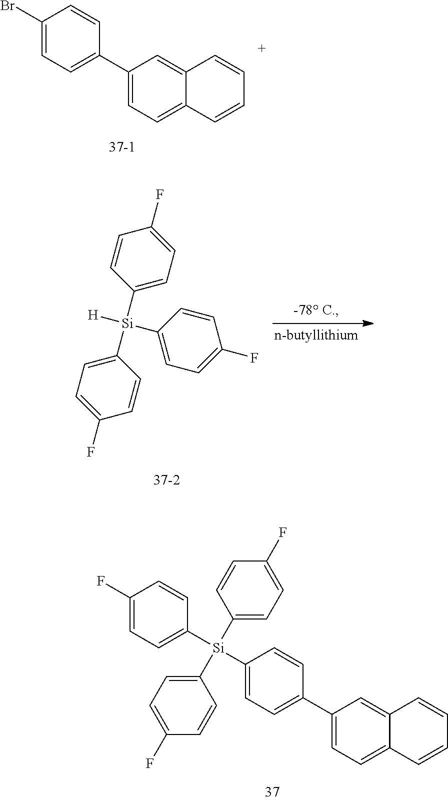 [SMILES: Brc1ccc(-c2ccc3ccccc3c2)cc1 ; Fc1ccc([SiH](c2ccc(F)cc2)c2ccc(F)cc2)cc1 ; Fc1ccc([Si](c2ccc(F)cc2)(c2ccc(F)cc2)c2ccc(-c3ccc4ccccc4c3)cc2)cc1]

(1) Compound 37-1 (75 mmol) was dissolved in anhydrous THF, cooled to −78° C., slowly added dropwise with 150 mmol n-butyllithium, and then naturally warmed to room temperature for reaction overnight. The next day, the reaction solution was added with compound 37-2 (100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction, and the extraction was performed three times. Then the solvent was removed from the organic layer by using a rotary evaporator and the organic layer was subjected to column chromatography, crude product 37 was obtained.

The structure of target product 37 was determined by MALDI-TOF MS (MALDI coupled to time-of-flight mass spectrometry), MALDI-TOF MS (m/z): C₃₄H₂₃F₃Si. The theoretical value is 516.6, and the measured value is 516.2.

Elemental analysis: theoretical value C: 79.04, H: 4.49; measured value C: 79.03, H: 4.49.

### Example 4

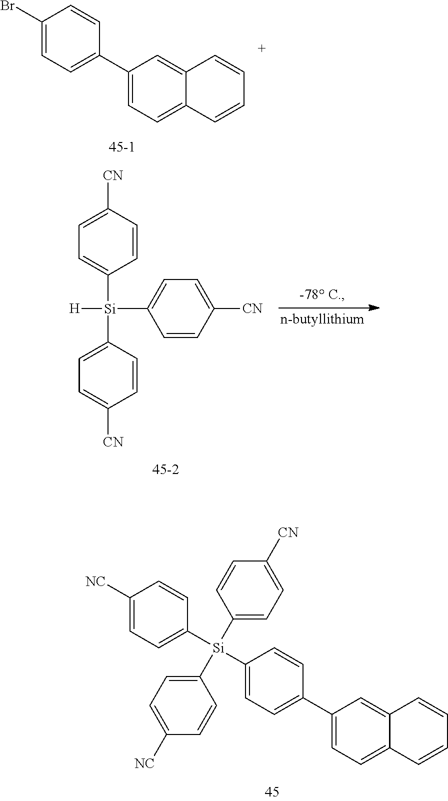 [SMILES: Brc1ccc(-c2ccc3ccccc3c2)cc1 ; N#Cc1ccc([SiH](c2ccc(C#N)cc2)c2ccc(C#N)cc2)cc1 ; N#Cc1ccc([Si](c2ccc(C#N)cc2)(c2ccc(C#N)cc2)c2ccc(-c3ccc4ccccc4c3)cc2)cc1]

(1) Compound 45-1 (75 mmol) was dissolved in anhydrous THF, cooled to −78° C., slowly added dropwise with 150 mmol n-butyllithium, and then naturally warmed to room temperature for reaction overnight. The next day, the reaction solution was added with compound 45-2 (100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction, and the extraction was performed three times. Then the solvent was removed from the organic layer by using a rotary evaporator and the organic layer was subjected to column chromatography, crude product 37 was obtained.

The structure of target product 45 was determined by MALDI-TOF MS (MALDI coupled to time-of-flight mass spectrometry), MALDI-TOF MS (m/z): C₃₇H₂₃N₃Si. The theoretical value is 537.7, and the measured value is 537.2.

Elemental analysis: theoretical value C: 82.65, H: 4.31, N: 7.81; measured value C: 82.64, H: 4.31, N: 7.82.

### Example 5

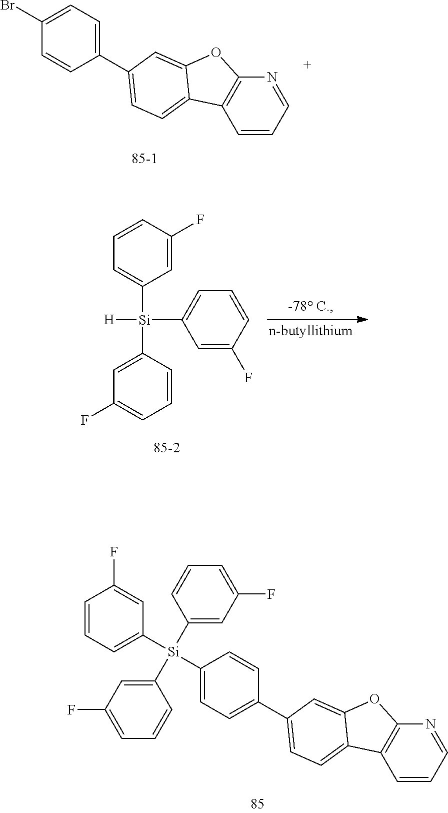 [SMILES: Brc1ccc(-c2ccc3c(c2)oc2ncccc23)cc1 ; Fc1cccc([SiH](c2cccc(F)c2)c2cccc(F)c2)c1 ; Fc1cccc([Si](c2ccc(-c3ccc4c(c3)oc3ncccc34)cc2)(c2cccc(F)c2)c2cccc(F)c2)c1]

(1) Compound 85-1 (75 mmol) was dissolved in anhydrous THF, cooled to −78° C., slowly added dropwise with 150 mmol n-butyllithium, and then naturally warmed to room temperature for reaction overnight. The next day, the reaction solution was added with compound 85-2 (100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction, and the extraction was performed three times. Then the solvent was removed from the organic layer by using a rotary evaporator and the organic layer was subjected to column chromatography, crude product 85 was obtained.

The structure of target product 85 was determined by MALDI-TOF MS (MALDI coupled to time-of-flight mass spectrometry), MALDI-TOF MS (m/z): C₃₅H₂₂OF₃NSi. The theoretical value is 557.6, and the measured value is 557.1.

Elemental analysis: theoretical value C: 75.39, H: 3.98, N: 2.51; measured value C: 75.39, H: 3.99, N: 2.51.

### Example 6

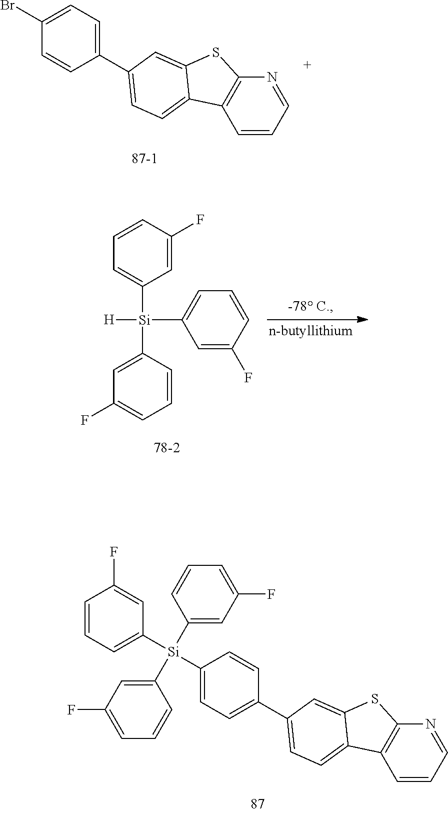 [SMILES: Brc1ccc(-c2ccc3c(c2)sc2ncccc23)cc1 ; Fc1cccc([SiH](c2cccc(F)c2)c2cccc(F)c2)c1 ; Fc1cccc([Si](c2ccc(-c3ccc4c(c3)sc3ncccc34)cc2)(c2cccc(F)c2)c2cccc(F)c2)c1]

(1) Compound 87-1 (75 mmol) was dissolved in anhydrous THF, cooled to −78° C., slowly added dropwise with 150 mmol n-butyllithium, and then naturally warmed to room temperature for reaction overnight. The next day, the reaction solution was added with compound 87-2 (100 mmol), stirred at room temperature for 3 h, and then slowly warmed up for reflux reaction for 3 h. After the reaction was completed, the reaction solution was cooled to room temperature and slowly added with saturated MgSO₄ aqueous solution and ethyl acetate for extraction, and the extraction was performed three times. Then the solvent was removed from the organic layer by using a rotary evaporator and the organic layer was subjected to column chromatography, crude product 87 was obtained.

The structure of target product 87 was determined by MALDI-TOF MS (MALDI coupled to time-of-flight mass spectrometry), MALDI-TOF MS (m/z): C₃₅H₂₂F₃NSSi. The theoretical value is 573.7, and the measured value is 573.1.

Elemental analysis: theoretical value C: 73.28, H: 3.87, N: 2.44; measured value C: 73.27, H: 3.87, N: 2.44.

The methods for preparing other compounds of the present disclosure are similar to the above methods, and not to go into details one by one. The characterization results from mass spectrometry analysis and elemental analysis of some other compounds of the present disclosure are provided in Table 1.

TABLE 1
Characterization results of compounds

| | Mass spectrometry | | | |
|---|---|---|---|---|
| | Results | | | |
| | Theoretical | Measured | Elemental analysis results | |
| Compound | value | value | Theoretical value | Measured value |
| 2 | 629.7 | 629.2 | C, 80.10; H, 4.16; N, 2.22; | C, 80.10; H, 4.17; N, 2.22; |
| 3 | 778.8 | 778.2 | C, 70.94; H, 3.49; | C, 70.93; H, 3.49; |
| 5 | 599.8 | 599.2 | C, 88.11; H, 4.87; N, 2.34; | C, 88.12; H, 4.87; N, 2.33; |
| 15 | 758.8 | 758.2 | C, 77.56; H, 3.72; | C, 77.56; H, 3.73; |
| 18 | 800.9 | 800.2 | C, 77.98; H, 4.28; | C, 77.98; H, 4.28; |
| 38 | 517.6 | 517.2 | C, 76.57; H, 4.28; N, 2.71; | C, 76.57; H, 4.28; N, 2.70; |
| 73 | 620.8 | 620.2 | C, 77.40; H, 4.38; N, 4.51; | C, 77.40; H, 4.38; N, 4.51; |
| 102 | 690.7 | 690.2 | C, 73.03; H, 3.65; | C, 73.03; H, 3.66; |

### Performance Test: Characterization of Refractive Index

The refractive index of the compounds at the wavelength of 460 nm, 530 nm and 620 nm was measured by an ellipsometer. The refractive index differences are calculated, and Δn1 is the difference of refractive indexes at the wavelength of 460 nm and 530 nm, Δn2 is the 5 difference of refractive indexes at the wavelength of 530 nm and 620 nm, and Δn3 is the difference of refractive indexes at the wavelength of 460 nm and 620 nm.

The above test results are shown in Table 2.

TABLE 2

| Compound | n_{460 nm} | n_{530 nm} | n_{620 nm} | Δn₁ | Δn₂ | Δn₃ |
|---|---|---|---|---|---|---|
| 1 | 1.76 | 1.73 | 1.70 | 0.03 | 0.03 | 0.06 |
| 2 | 1.77 | 1.71 | 1.68 | 0.06 | 0.03 | 0.09 |
| 3 | 1.70 | 1.67 | 1.65 | 0.03 | 0.02 | 0.05 |
| 5 | 1.80 | 1.74 | 1.70 | 0.06 | 0.04 | 0.10 |
| 7 | 1.76 | 1.72 | 1.70 | 0.04 | 0.02 | 0.06 |
| 15 | 1.72 | 1.67 | 1.66 | 0.05 | 0.01 | 0.06 |
| 18 | 1.72 | 1.67 | 1.66 | 0.05 | 0.01 | 0.06 |
| 37 | 1.68 | 1.65 | 1.64 | 0.03 | 0.01 | 0.04 |
| 38 | 1.69 | 1.66 | 1.65 | 0.03 | 0.01 | 0.04 |
| 45 | 1.68 | 1.64 | 1.63 | 0.04 | 0.01 | 0.05 |
| 73 | 1.77 | 1.71 | 1.67 | 0.06 | 0.04 | 0.10 |
| 85 | 1.70 | 1.68 | 1.66 | 0.02 | 0.02 | 0.04 |
| 87 | 1.70 | 1.67 | 1.65 | 0.03 | 0.02 | 0.05 |
| 102 | 1.70 | 1.66 | 1.64 | 0.04 | 0.02 | 0.06 |
| C1 | 2.12 | 2.00 | 1.90 | 0.12 | 0.10 | 0.22 |
| C2 | 2.20 | 2.06 | 1.96 | 0.14 | 0.10 | 0.24 |
| C3 | 2.06 | 1.94 | 1.84 | 0.12 | 0.10 | 0.22 |

The structures of comparative compounds C1, C2 and C3 are as follows:

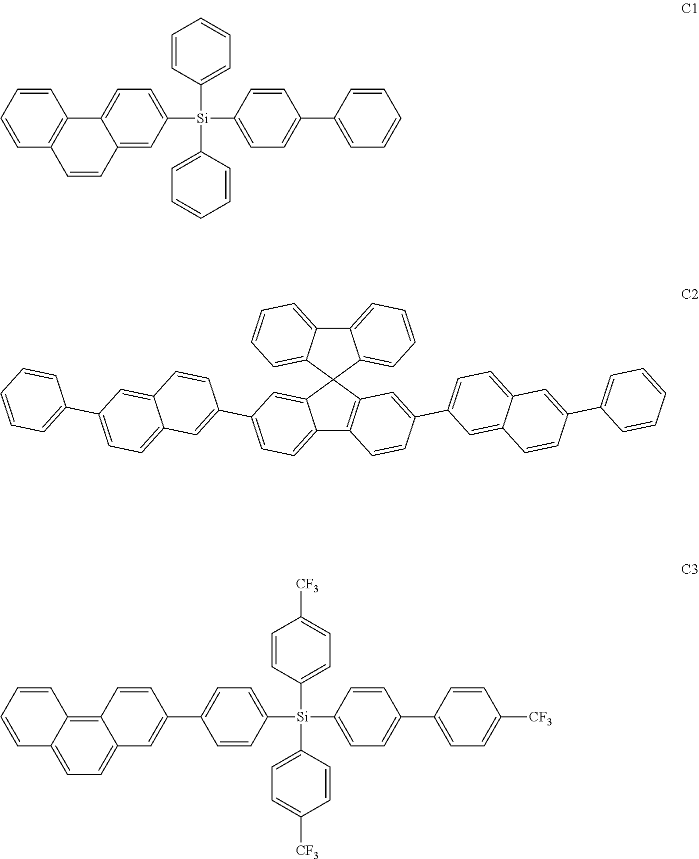

As shown in Table 2, the compounds provided by the present disclosure satisfy the following requirements: the difference value between the refractive index at the wavelength of 460 nm and the refractive index at the wavelength of 530 nm is 0.02-0.06, the difference value between the refractive index at the wavelength of 530 nm and the refractive index at the wavelength of 620 nm is 0.01-0.04, and the difference value between the refractive index at the wavelength of 460 nm and the refractive index at the wavelength of 620 nm is 0.04-0.10. When used in organic electroluminescent devices, the compounds provided by the present disclosure can effectively improve color shift in realizing multi-angle display due to the small Δn meaning a small difference in refractive index under different light colors. Although compounds C1, C2, and C3 have similar structures to the compounds of the present disclosure, the arylsilyl group of C1 is substituted with a fused ring group having three benzene rings, resulting in enhanced planarity of the molecule and an increased refractive index. Although C2 has a spirofluorenyl group with good stereoscopicity and large size, no Si atom is introduced into the molecule, and the spirofluorenyl group is directly connected to the highly planar conjugated aryl group, resulting in an increase in the conjugated area of the entire molecule. Although compound C3 is connected to a substituent containing F which helps to reduce the refractive index of the molecule, the silicon group is substituted with a fused ring group with three benzene rings, resulting in enhanced planarity of the molecule and an increased refractive index.

In order to facilitate understanding of the present disclosure, examples of using the compounds of the present disclosure are listed below. The examples are only to help understand the present disclosure and should not be regarded as specific limitations of the present disclosure.

### Application Example 1

In this example, an organic electroluminescent device is provided, the structure of which is shown in the FIGURE. The specific preparation steps are as follows:

1) A glass substrate with indium tin oxide (ITO) anode layer 2 (thickness: 15 nm) was cut into a size of 50 mm×50 mm×0.7 mm, sonicated in isopropyl alcohol and deionized water for 30 min respectively, and then exposed in ozone to clean for about 10 min. The cleaned substrate 1 was installed on a vacuum deposition equipment.

2) On the ITO anode layer 2, compounds a and b (b is p-type doping material, 3% doping ratio in mass), which were hole injection layer materials, were evaporated through vacuum evaporation to a thickness of 5 nm, serving as hole injection layer 3.

3) Compound b, the hole-transporting layer material, was evaporated on hole injection layer 3 through vacuum evaporation to a thickness of 100 nm, serving as first hole-transporting layer 4.

4) Compound c, the hole-transporting layer material, was evaporated on first hole-transporting layer 4 through vacuum evaporation to a thickness of 5 nm, serving as second hole-transporting layer 5.

5) A light-emitting layer 6 was evaporated on second hole-transporting layer 5 through vacuum evaporation to a thickness of 30 nm, in which compound d was used as the host material and compound e was used as the doping material at a doping ratio of 3% in mass.

6) Compound f, the electron-transporting layer material, was evaporated on light-emitting layer 6 through vacuum evaporation to a thickness of 30 nm, serving as first electron-transporting layer 7.

7) Compounds g and h doped with doping material n (1:1 doping ratio in mass), which were electron-transporting layer materials, was evaporated on first electron-transporting layer 7 through vacuum evaporation to a thickness of 5 nm, serving as second electron-transporting layer 8.

8) A magnesium silver electrode (Mg:Ag of 9:1) was evaporated on second electron-transporting layer 8 through vacuum evaporation to a thickness of 10 nm, serving as cathode 9.

9) Compound i was evaporated on cathode 9 through vacuum evaporation to a thickness of 100 nm, serving as first capping layer 10.

10) The organic small molecule compound 1 with low refractive index of the present disclosure was evaporated on the first capping layer through vacuum evaporation to a thickness of 20 nm, serving as second capping layer 11.

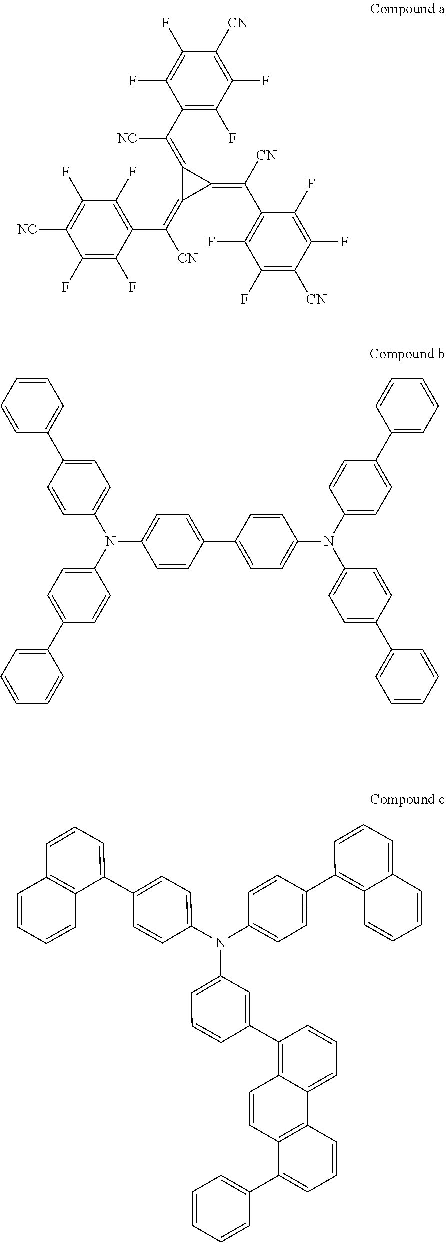 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2cccc3c2ccc2c(-c4cccc(N(c5ccc(-c6cccc7ccccc67)cc5)c5ccc(-c6cccc7ccccc67)cc5)c4)cccc23)cc1]

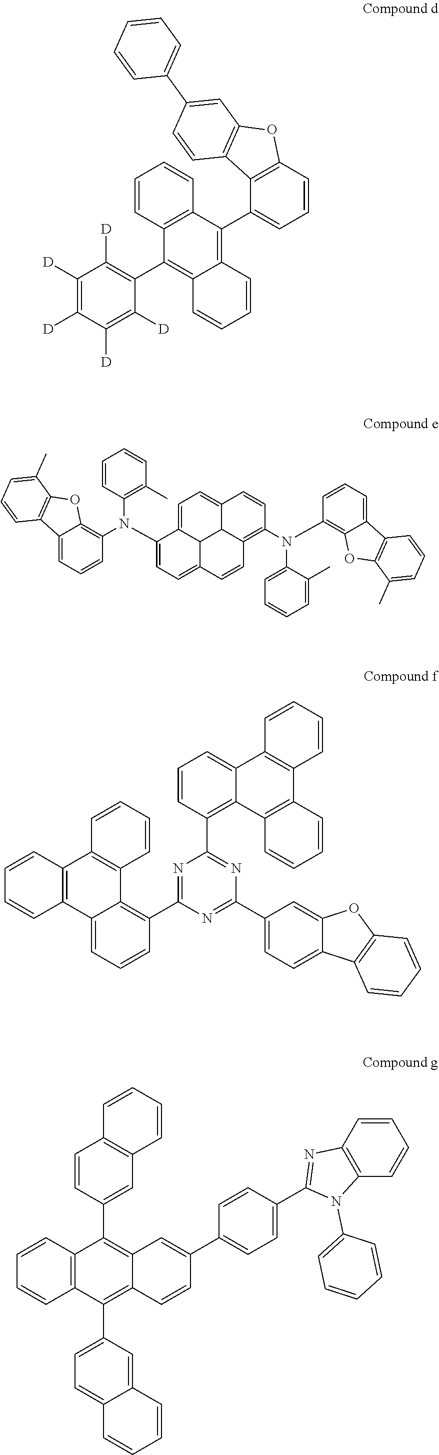 [SMILES: [2H]c1c([2H])c([2H])c(-c2c3ccccc3c(-c3cccc4oc5cc(-c6ccccc6)ccc5c34)c3ccccc23)c([2H])c1[2H] ; Cc1ccccc1N(C1=CC=C2C=CC3=C(N(c4ccccc4C)c4cccc5c4oc4c(C)cccc45)C=CC4=CC=C1C2C43)c1cccc2c1oc1c(C)cccc12 ; c1ccc2c(c1)oc1cc(-c3nc(-c4cccc5c6ccccc6c6ccccc6c45)nc(-c4cccc5c6ccccc6c6ccccc6c45)n3)ccc12 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

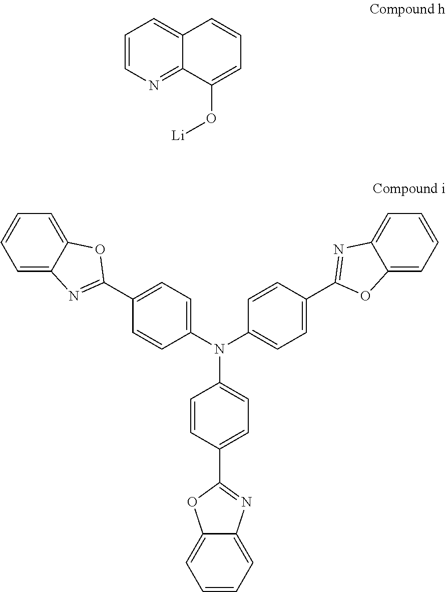

### Application Examples 2-14

Application Examples 2-14 are similar with Application Example 1, except that compounds 2, 3, 5, 7, 15, 18, 37, 38, 45, 73, 85, 87 and 102 are respectively used to prepare the second capping layer in step 10), instead of compound 1 in Application Example 1.

### Comparative Examples 1-3

In Comparative Examples 1-3, instead of using compound 1, C1-C3 are respectively used to prepare the second capping layer in step 10).

### Performance Test

Based on the Application examples 1-14 and Comparative examples 1-3, the organic electroluminescent devices prepared by using the compounds of the present disclosure were subjected to the following performance tests.

The current of the organic electroluminescent device was measured at different voltages by using Keithley 2365A digital nanovoltmeter, and the current density of the organic photoelectric device at different voltages was calculated by dividing the current by the light-emitting area. The brightness and radiant energy flux density of the organic electroluminescent device prepared according to the above examples were measured at different voltages by using Konicaminolta CS-2000 spectroradiometer. According to the current density and brightness of the organic electroluminescent device at different voltages, the operating voltage Von (V), current efficiency CE (cd/A) and color shift JNCD (30° C./45/60° C.) at the same current density (10 mA/cm²) were obtained. The results are shown in Table 3.

TABLE 3

| | | | CE_{(10 mA/cm}_{²}₎ | |
|---|---|---|---|---|
| No. | Compound | Vₒₙ (V) | (cd A⁻¹) | JNCD |
| Application example 1 | 1 | 3.51 | 7.88 | 3/2/1 |
| Application example 2 | 2 | 3.50 | 7.90 | 4/3/1 |
| Application example 3 | 3 | 3.53 | 8.09 | 3/1/1 |
| Application example 4 | 5 | 3.52 | 7.90 | 3/2/1 |
| Application example 5 | 7 | 3.50 | 7.94 | 4/2/1 |
| Application example 6 | 15 | 3.52 | 8.12 | 4/3/1 |
| Application example 7 | 18 | 3.49 | 8.15 | 4/4/1 |
| Application example 8 | 37 | 3.49 | 8.18 | 4/3/1 |
| Application example 9 | 38 | 3.50 | 8.17 | 4/2/1 |
| Application example 10 | 45 | 3.53 | 8.20 | 4/2/2 |
| Application example 11 | 73 | 3.52 | 7.92 | 3/2/1 |
| Application example 12 | 85 | 3.50 | 8.01 | 4/1/3 |
| Application example 13 | 87 | 3.49 | 8.09 | 4/3/1 |
| Application example 14 | 102 | 3.49 | 8.18 | 3/3/1 |
| Comparative example 1 | C1 | 3.51 | 6.69 | 6/3/3 |
| Comparative example 2 | C2 | 3.51 | 6.85 | 5/8/7 |
| Comparative example 3 | C3 | 3.50 | 7.09 | 6/3/2 |

As can be seen from Table 3, compared with using compound C1, C2 or C3, when the compounds provided by the present disclosure were used as the material of the second capping layer and matched with the first capping layer material containing organic small molecules with high refractive index, the voltages of the obtained devices are basically the same, while the devices prepared using the compounds of the present disclosure had higher efficiency and significant advantage on improving color shift.

The description of the above embodiments is only used to help understand the method and the embodiments of the present disclosure. Several improvements and modifications to the present disclosure without departing from the principles of the present disclosure may be made, and these improvements and modifications also fall within the scope of the claims of the present disclosure.

What is claimed is:

1. A compound with low refractive index, having a structure represented by Formula I: 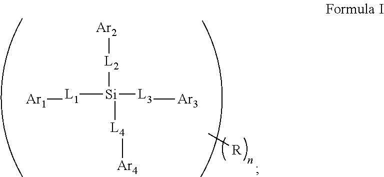
wherein, L₁-L₄ are independently selected from the group consisting of a single bond, a substituted or unsubstituted C6-C18 arylene, and a substituted or unsubstituted C5-C18 heteroarylene;
at least one of Ar₁-Ar₄ is selected from structures represented by Formula II-Formula V, 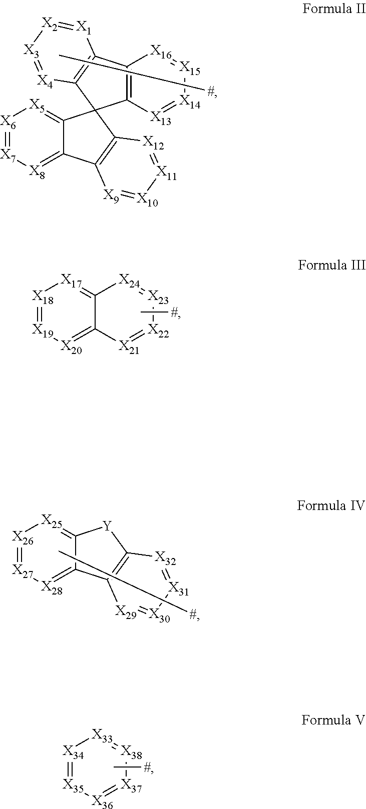
and the others are independently selected from the group consisting of substituted or unsubstituted C6-C30 aryl and substituted or unsubstituted C3-C30 heteroaryl;
X₁-X₃₈ are independently CH or N;
Y is selected from the group consisting of CR₁R₂, O and S;
R₁ and R₂ are independently H or C1-C3 alkyl;
R is selected from the group consisting of F, alkyl containing F, CN, substituted or unsubstituted C6-C30 aryl, and substituted or unsubstituted C3-C30 heteroaryl; wherein a substituent of the C6-C30 aryl or the C3-C30 heteroaryl is selected from the group consisting of CN, F, C1-C5 alkyl containing F, and a combination thereof;
n is the number of R and n>1; and
# indicates a linking position.

2. The compound with low refractive index according to claim 1, wherein L₁-L₄ are independently selected from the group consisting of a single bond, substituted or unsubstituted phenylene, pyridinylene, pyrimidinylene, pyrazinylene, pyridazinylidene, triazinylidene, biphenylene, naphthylene, quinolinylidene, isoquinolinylidene, quinoxalinylidene and quinazolinylidene.

3. The compound with low refractive index according to claim 1, wherein L₁-L₄ are independently selected from the group consisting of a single bond, 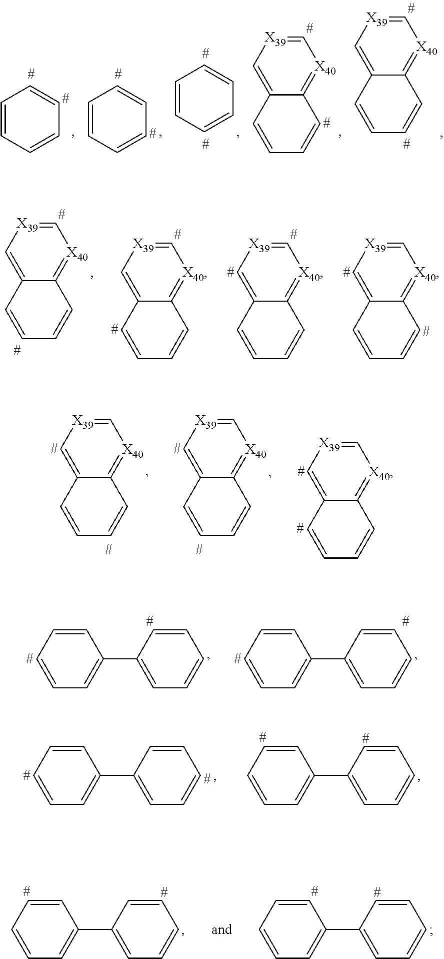
X₃₉ and X₄₀ are independently CH or N; and
# indicates a linking position.

4. The compound with low refractive index according to claim 1, wherein R is selected from the group consisting of F, C1-C5 alkyl containing 1-3 F atoms, CN, substituted or unsubstituted phenyl, substituted or unsubstituted pyridyl; and a substituent of the phenyl or pyridyl is selected from the group consisting of CN, F, CF₃, CHF₂, CH₂F and a combination thereof.

5. The compound with low refractive index according to claim 4, wherein the phenyl or pyridyl contains more than one substituents, and the more than one substituents are arranged in meta position.

6. The compound with low refractive index according to claim 4, wherein R is selected from the group consisting of F, CN, CHF₂, CH₂F, CF₃,

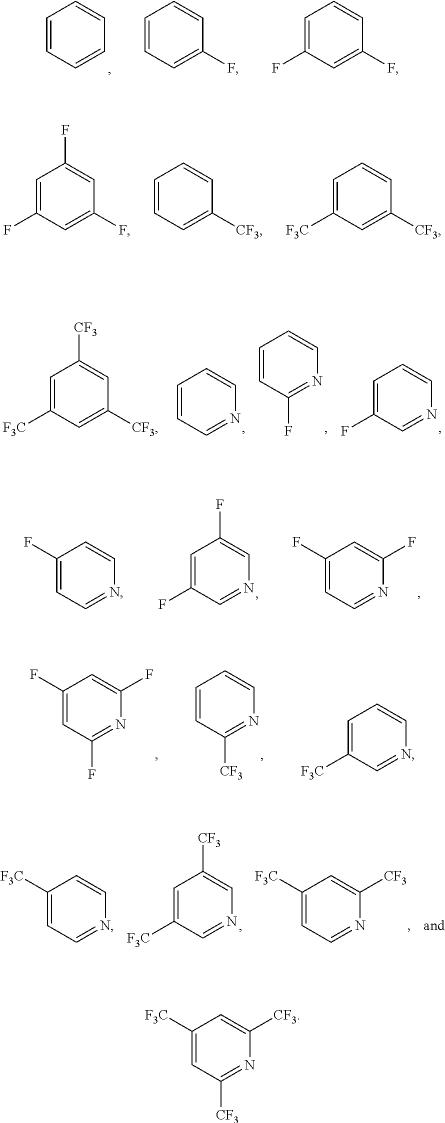

7. The compound with low refractive index according to claim 1, wherein n is an integer selected from 1 to 8.

8. The compound with low refractive index according to claim 1, wherein
X₁-X₁₆ are all CH, or one or two of X₁-X₁₆ are N, and the others are CH; and the structure represented by Formula II is connected to any one of L₁-L₄ of parent structure through C atom;
X₁₇-X₂₄ are all CH, or one or two of X₁₇-X₂₄ are N, and the others are CH; and the structure represented by Formula III is connected to parent structure through C atom;
X₂₅-X₃₂ are all CH, or one or two of X₂₅-X₃₂ are N, and the others are CH; and the structure represented by Formula IV is connected to parent structure through C atom; or
X₃₃-X₃₅ are all CH, or one or three of X₃₃-X₃₅ are N, and the others are CH; and the structure represented by Formula V is connected to parent structure through C atom.

9. The compound with low refractive index according to claim 1, wherein the structure represented by Formula II is selected from the group consisting of:

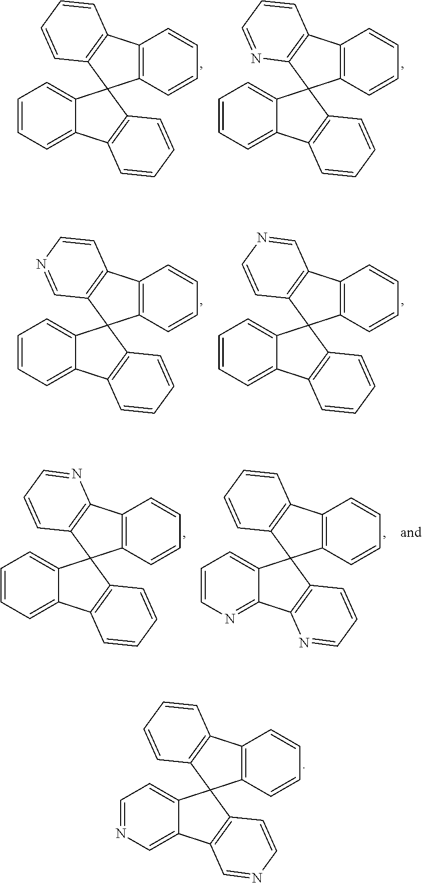

10. The compound with low refractive index according to claim 1, wherein the structure represented by Formula III is selected from the group consisting of:

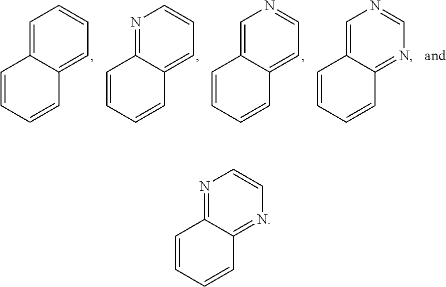

11. The compound with low refractive index according to claim 1, wherein the structure represented by Formula IV is selected from the group consisting of: 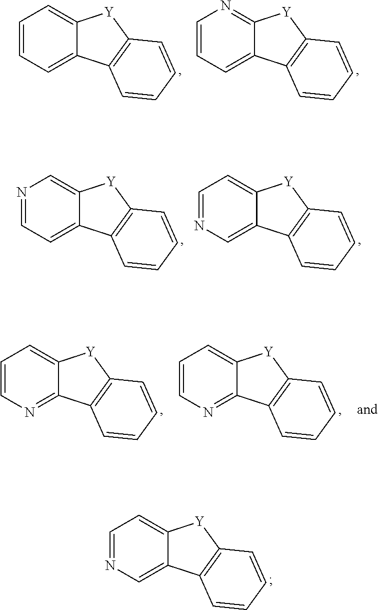
and
Y is selected from the group consisting of CH₂, C(CH₃)₂, O and S.

12. The compound with low refractive index according to claim 1, wherein the structure represented by Formula V is selected from the group consisting of:

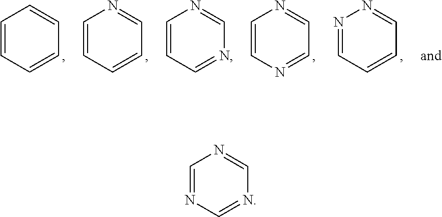

13. The compound with low refractive index according to claim 1, wherein
the C6-C30 aryl is phenyl or a group formed by connecting 2 or 3 phenyl groups through a single bond; and
the C3-C30 heteroaryl is selected from the group consisting of five-membered or six-membered monocyclic heteroaryl, fused-ring heteroaryl formed by a fusion of 1 or 2 five-membered or six-membered monocyclic heteroaryl groups and 1 or 2 phenyl groups, and fused-ring heteroaryl formed by a fusion of 2 or 3 five-membered or six-membered monocyclic heteroaryl groups.

14. The compound with low refractive index according to claim 13, wherein
the C6-C30 aryl is selected from the group consisting of phenyl, biphenyl and terphenyl; and
the C3-C30 heteroaryl is selected from the group consisting of pyrrolyl, pyridyl, pyrazinyl, pyrimidinyl, triazinyl, quinolyl, isoquinolyl, quinoxalinyl and quinazolinyl.

15. The compound with low refractive index according to claim 1, wherein
one of Ar₁-Ar₄ is selected from the group consisting of structures represented by Formula II-Formula IV, and the others are the structure represented by Formula V;
all of Ar₁-Ar₄ are the structure represented by Formula V; or
two or three of Ar₁-Ar₄ are the structure represented by Formula III, and the others are the structure represented by Formula V.

16. The compound with low refractive index according to claim 15, wherein two of Ar₁-Ar₄ are the structure represented by Formula III, wherein Ar₁ and Ar₃ are the structure represented by Formula III or Ar₂ and Ara are the structure represented by Formula III.

17. The compound with low refractive index according to claim 1, which is selected from the group consisting of:

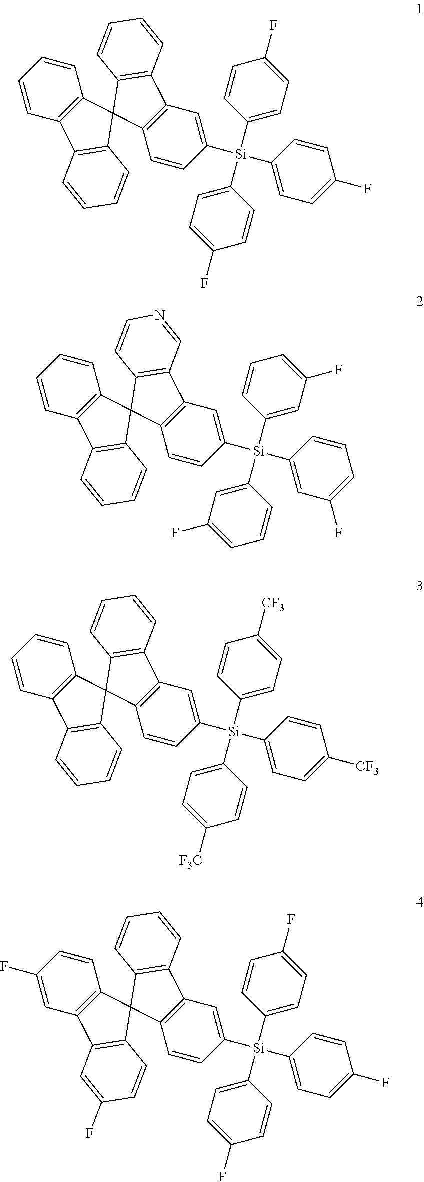 [SMILES: Fc1ccc([Si](c2ccc(F)cc2)(c2ccc(F)cc2)c2ccc3c(c2)-c2ccccc2C32c3ccccc3-c3ccccc32)cc1 ; Fc1cccc([Si](c2cccc(F)c2)(c2cccc(F)c2)c2ccc3c(c2)-c2cnccc2C32c3ccccc3-c3ccccc32)c1 ; FC(F)(F)c1ccc([Si](c2ccc(C(F)(F)F)cc2)(c2ccc(C(F)(F)F)cc2)c2ccc3c(c2)-c2ccccc2C32c3ccccc3-c3ccccc32)cc1 ; Fc1ccc([Si](c2ccc(F)cc2)(c2ccc(F)cc2)c2ccc3c(c2)-c2ccccc2C32c3ccc(F)cc3-c3cc(F)ccc32)cc1]

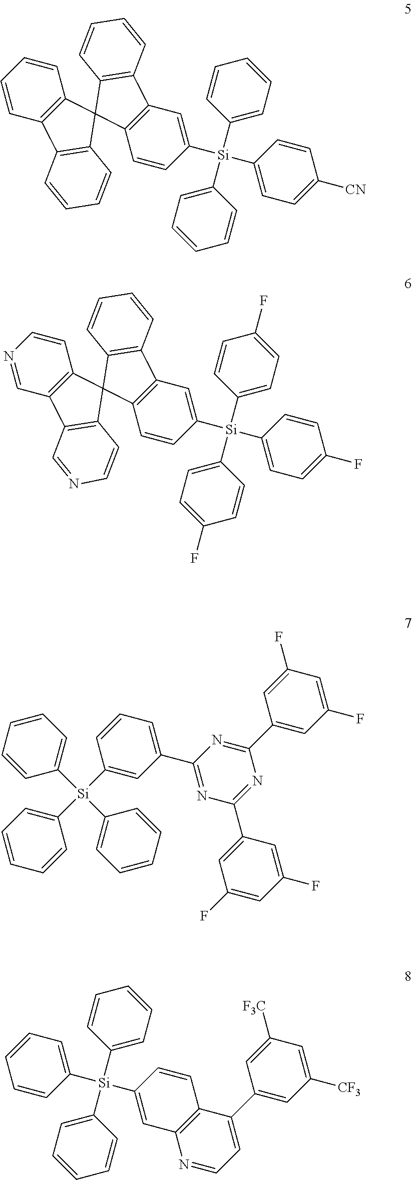 [SMILES: N#Cc1ccc([Si](c2ccccc2)(c2ccccc2)c2ccc3c(c2)-c2ccccc2C32c3ccccc3-c3ccccc32)cc1 ; Fc1ccc([Si](c2ccc(F)cc2)(c2ccc(F)cc2)c2ccc3c(c2)-c2ccccc2C32c3ccncc3-c3cnccc32)cc1 ; Fc1cc(F)cc(-c2nc(-c3cc(F)cc(F)c3)nc(-c3cccc([Si](c4ccccc4)(c4ccccc4)c4ccccc4)c3)n2)c1 ; FC(F)(F)c1cc(-c2ccnc3cc([Si](c4ccccc4)(c4ccccc4)c4ccccc4)ccc23)cc(C(F)(F)F)c1]

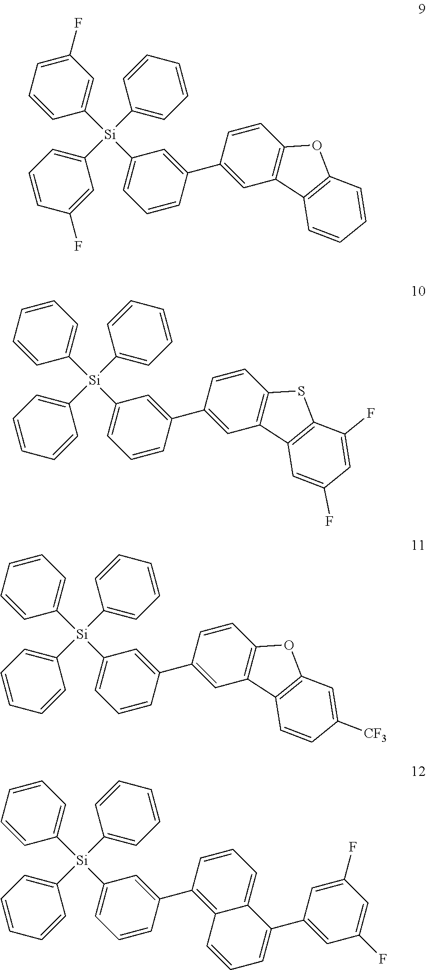 [SMILES: Fc1cccc([Si](c2ccccc2)(c2cccc(F)c2)c2cccc(-c3ccc4oc5ccccc5c4c3)c2)c1 ; Fc1cc(F)c2sc3ccc(-c4cccc([Si](c5ccccc5)(c5ccccc5)c5ccccc5)c4)cc3c2c1 ; FC(F)(F)c1ccc2c(c1)oc1ccc(-c3cccc([Si](c4ccccc4)(c4ccccc4)c4ccccc4)c3)cc12 ; Fc1cc(F)cc(-c2cccc3c(-c4cccc([Si](c5ccccc5)(c5ccccc5)c5ccccc5)c4)cccc23)c1]

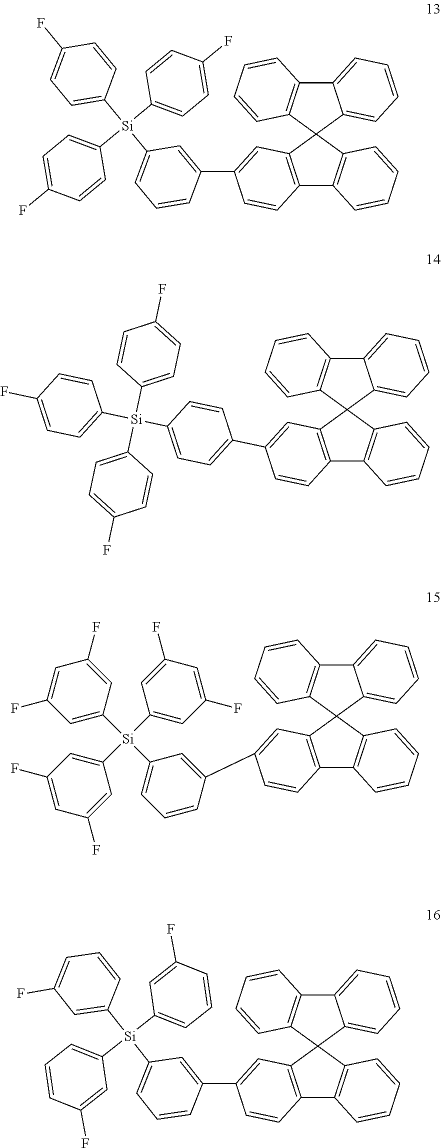 [SMILES: Fc1ccc([Si](c2ccc(F)cc2)(c2ccc(F)cc2)c2cccc(-c3ccc4c(c3)C3(c5ccccc5-c5ccccc53)c3ccccc3-4)c2)cc1 ; Fc1ccc([Si](c2ccc(F)cc2)(c2ccc(F)cc2)c2ccc(-c3ccc4c(c3)C3(c5ccccc5-c5ccccc53)c3ccccc3-4)cc2)cc1 ; Fc1cc(F)cc([Si](c2cc(F)cc(F)c2)(c2cc(F)cc(F)c2)c2cccc(-c3ccc4c(c3)C3(c5ccccc5-c5ccccc53)c3ccccc3-4)c2)c1 ; Fc1cccc([Si](c2cccc(F)c2)(c2cccc(F)c2)c2cccc(-c3ccc4c(c3)C3(c5ccccc5-c5ccccc53)c3ccccc3-4)c2)c1]

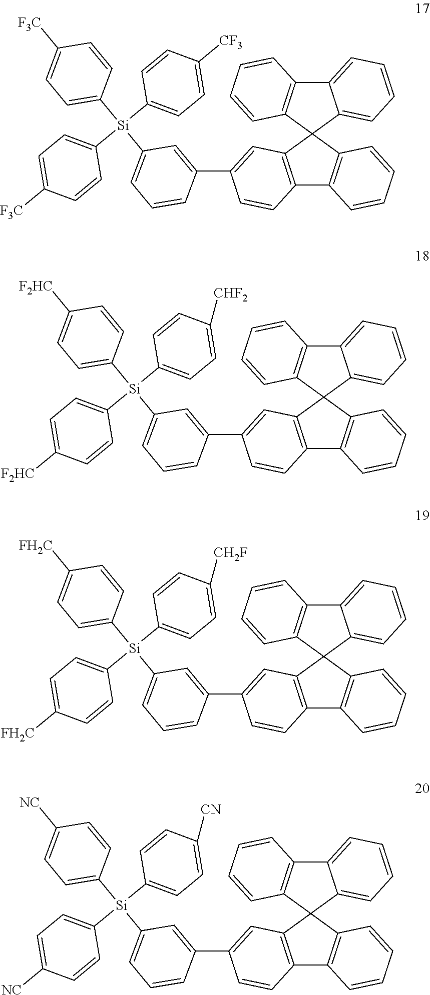

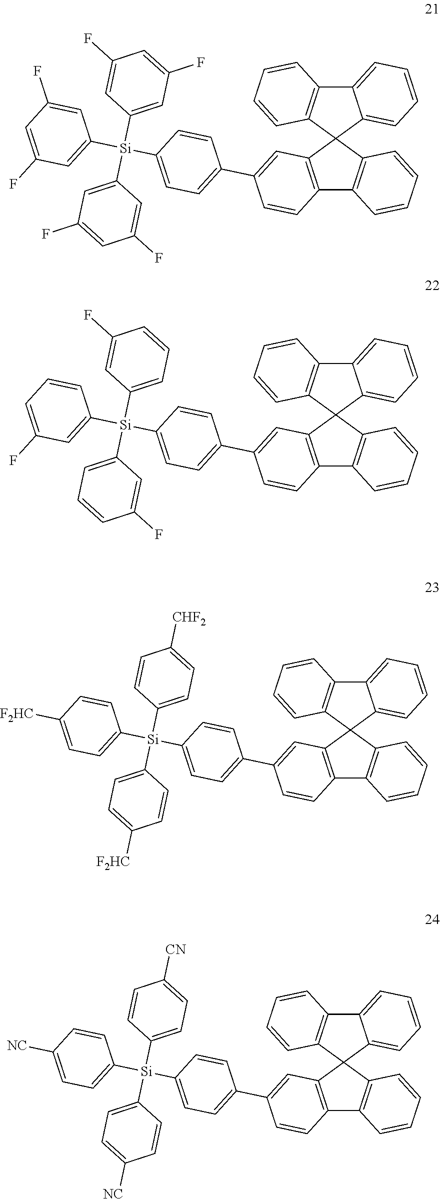 [SMILES: Fc1cc(F)cc([Si](c2ccc(-c3ccc4c(c3)C3(c5ccccc5-c5ccccc53)c3ccccc3-4)cc2)(c2cc(F)cc(F)c2)c2cc(F)cc(F)c2)c1 ; Fc1cccc([Si](c2ccc(-c3ccc4c(c3)C3(c5ccccc5-c5ccccc53)c3ccccc3-4)cc2)(c2cccc(F)c2)c2cccc(F)c2)c1 ; FC(F)c1ccc([Si](c2ccc(-c3ccc4c(c3)C3(c5ccccc5-c5ccccc53)c3ccccc3-4)cc2)(c2ccc(C(F)F)cc2)c2ccc(C(F)F)cc2)cc1 ; N#Cc1ccc([Si](c2ccc(C#N)cc2)(c2ccc(C#N)cc2)c2ccc(-c3ccc4c(c3)C3(c5ccccc5-c5ccccc53)c3ccccc3-4)cc2)cc1]

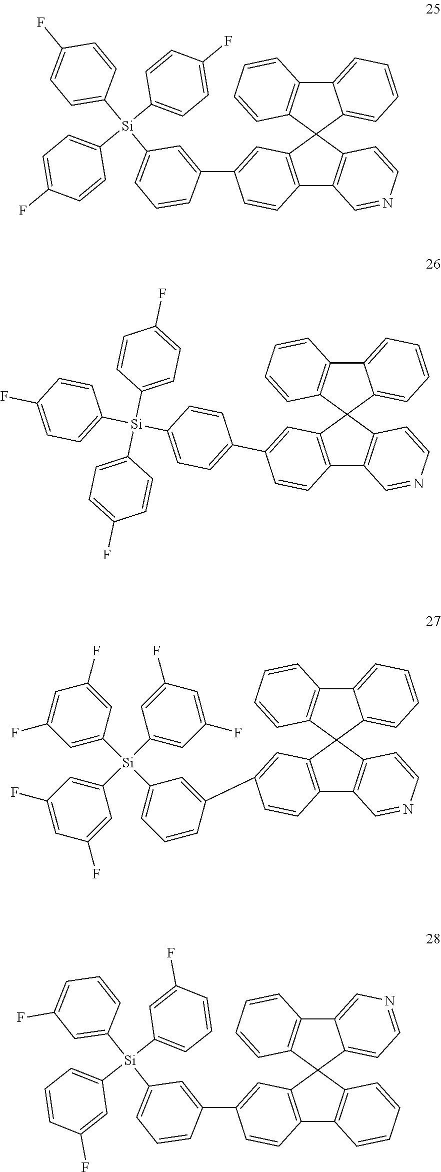 [SMILES: Fc1ccc([Si](c2ccc(F)cc2)(c2ccc(F)cc2)c2cccc(-c3ccc4c(c3)C3(c5ccccc5-c5ccccc53)c3ccncc3-4)c2)cc1 ; Fc1ccc([Si](c2ccc(F)cc2)(c2ccc(F)cc2)c2ccc(-c3ccc4c(c3)C3(c5ccccc5-c5ccccc53)c3ccncc3-4)cc2)cc1 ; Fc1cc(F)cc([Si](c2cc(F)cc(F)c2)(c2cc(F)cc(F)c2)c2cccc(-c3ccc4c(c3)C3(c5ccccc5-c5ccccc53)c3ccncc3-4)c2)c1 ; Fc1cccc([Si](c2cccc(F)c2)(c2cccc(F)c2)c2cccc(-c3ccc4c(c3)C3(c5ccccc5-c5cnccc53)c3ccccc3-4)c2)c1]

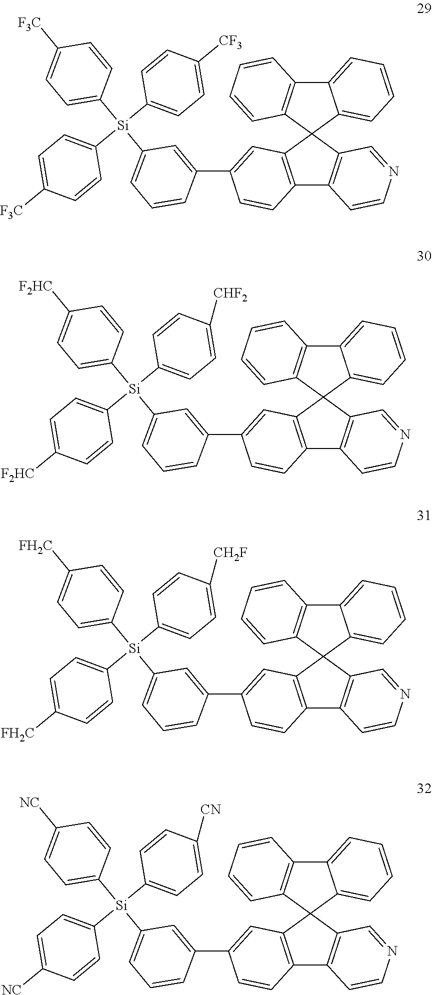

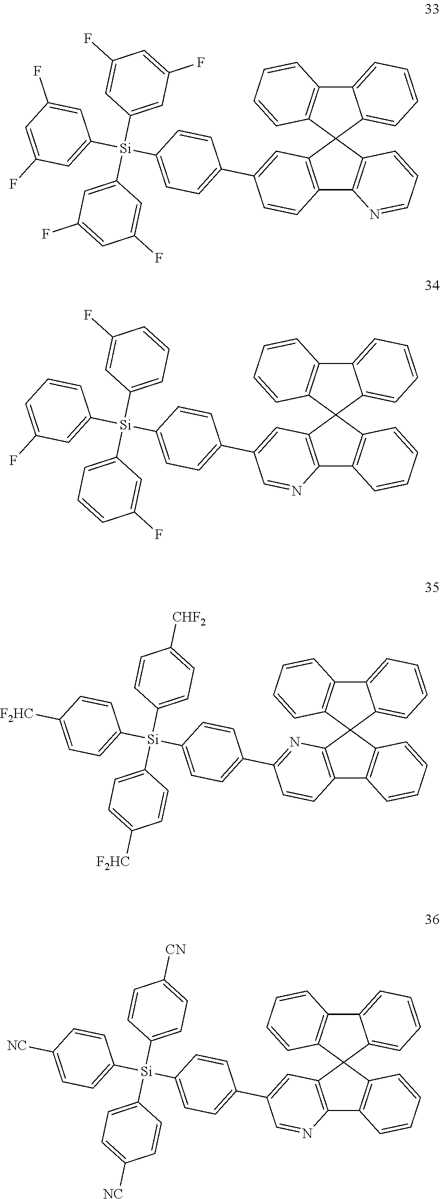 [SMILES: Fc1cc(F)cc([Si](c2ccc(-c3ccc4c(c3)C3(c5ccccc5-c5ccccc53)c3cccnc3-4)cc2)(c2cc(F)cc(F)c2)c2cc(F)cc(F)c2)c1 ; Fc1cccc([Si](c2ccc(-c3cnc4c(c3)C3(c5ccccc5-c5ccccc53)c3ccccc3-4)cc2)(c2cccc(F)c2)c2cccc(F)c2)c1 ; FC(F)c1ccc([Si](c2ccc(-c3ccc4c(n3)C3(c5ccccc5-c5ccccc53)c3ccccc3-4)cc2)(c2ccc(C(F)F)cc2)c2ccc(C(F)F)cc2)cc1 ; N#Cc1ccc([Si](c2ccc(C#N)cc2)(c2ccc(C#N)cc2)c2ccc(-c3cnc4c(c3)C3(c5ccccc5-c5ccccc53)c3ccccc3-4)cc2)cc1]

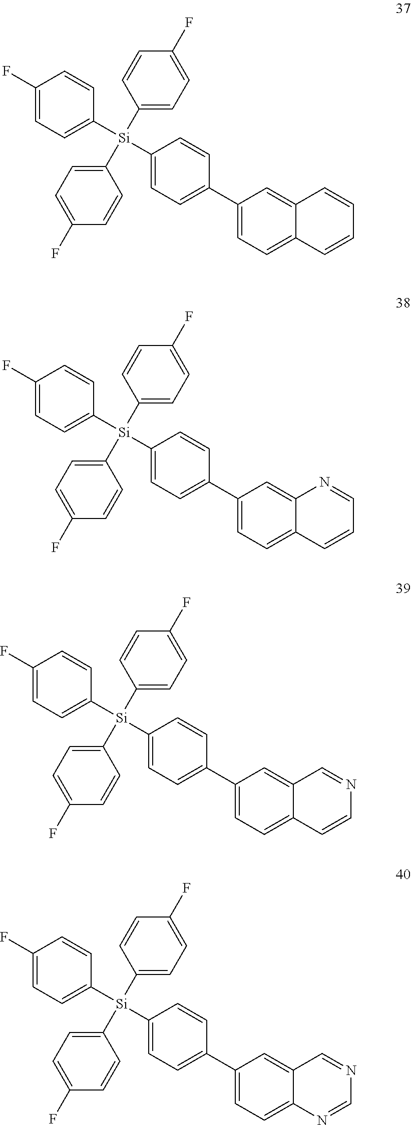 [SMILES: Fc1ccc([Si](c2ccc(F)cc2)(c2ccc(F)cc2)c2ccc(-c3ccc4ccccc4c3)cc2)cc1 ; Fc1ccc([Si](c2ccc(F)cc2)(c2ccc(F)cc2)c2ccc(-c3ccc4cccnc4c3)cc2)cc1 ; Fc1ccc([Si](c2ccc(F)cc2)(c2ccc(F)cc2)c2ccc(-c3ccc4ccncc4c3)cc2)cc1 ; Fc1ccc([Si](c2ccc(F)cc2)(c2ccc(F)cc2)c2ccc(-c3ccc4ncncc4c3)cc2)cc1]

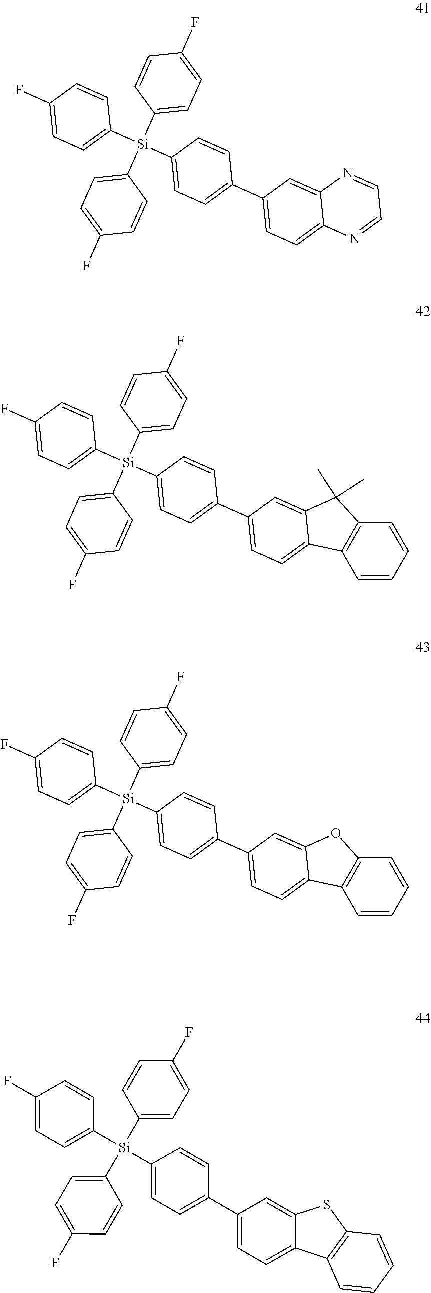 [SMILES: Fc1ccc([Si](c2ccc(F)cc2)(c2ccc(F)cc2)c2ccc(-c3ccc4nccnc4c3)cc2)cc1 ; CC1(C)c2ccccc2-c2ccc(-c3ccc([Si](c4ccc(F)cc4)(c4ccc(F)cc4)c4ccc(F)cc4)cc3)cc21 ; Fc1ccc([Si](c2ccc(F)cc2)(c2ccc(F)cc2)c2ccc(-c3ccc4c(c3)oc3ccccc34)cc2)cc1 ; Fc1ccc([Si](c2ccc(F)cc2)(c2ccc(F)cc2)c2ccc(-c3ccc4c(c3)sc3ccccc34)cc2)cc1]

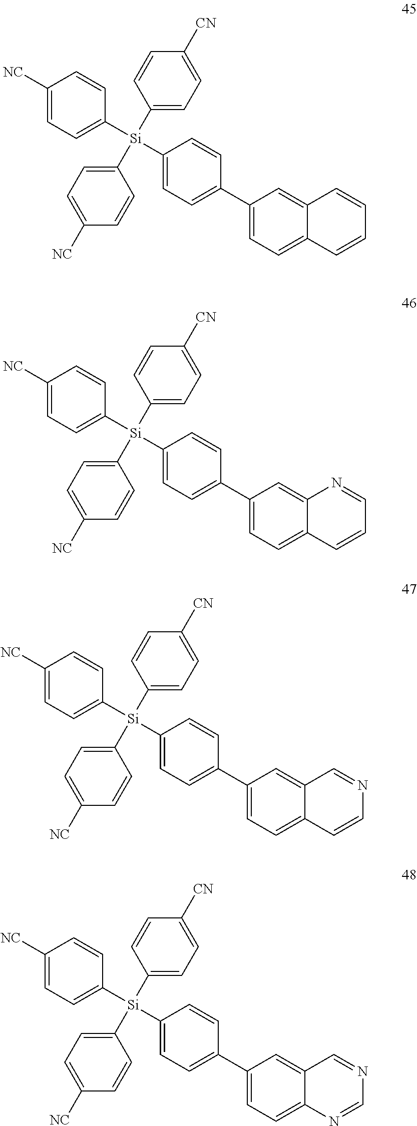 [SMILES: N#Cc1ccc([Si](c2ccc(C#N)cc2)(c2ccc(C#N)cc2)c2ccc(-c3ccc4ccccc4c3)cc2)cc1 ; N#Cc1ccc([Si](c2ccc(C#N)cc2)(c2ccc(C#N)cc2)c2ccc(-c3ccc4cccnc4c3)cc2)cc1 ; N#Cc1ccc([Si](c2ccc(C#N)cc2)(c2ccc(C#N)cc2)c2ccc(-c3ccc4ccncc4c3)cc2)cc1 ; N#Cc1ccc([Si](c2ccc(C#N)cc2)(c2ccc(C#N)cc2)c2ccc(-c3ccc4ncncc4c3)cc2)cc1]

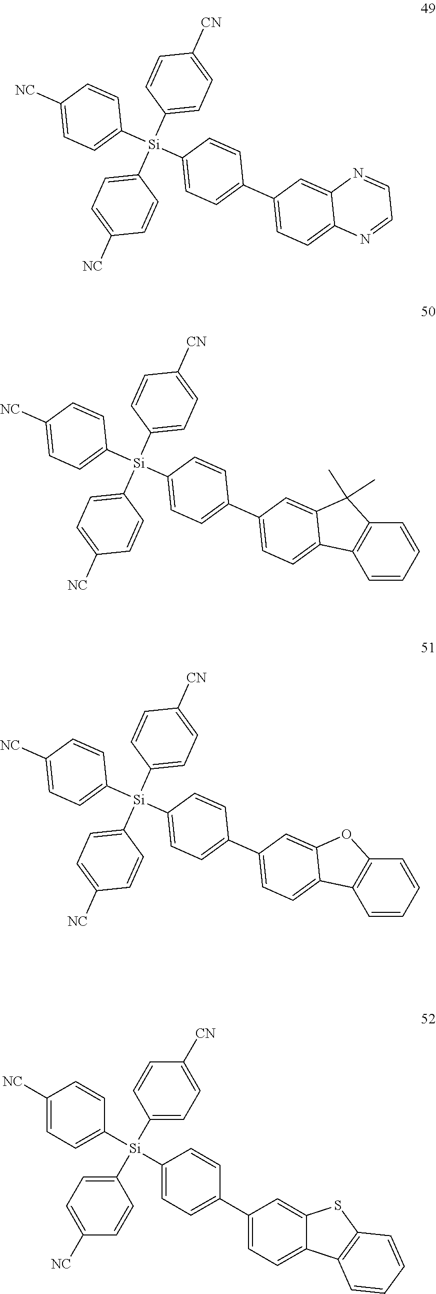 [SMILES: N#Cc1ccc([Si](c2ccc(C#N)cc2)(c2ccc(C#N)cc2)c2ccc(-c3ccc4nccnc4c3)cc2)cc1 ; CC1(C)c2ccccc2-c2ccc(-c3ccc([Si](c4ccc(C#N)cc4)(c4ccc(C#N)cc4)c4ccc(C#N)cc4)cc3)cc21 ; N#Cc1ccc([Si](c2ccc(C#N)cc2)(c2ccc(C#N)cc2)c2ccc(-c3ccc4c(c3)oc3ccccc34)cc2)cc1 ; N#Cc1ccc([Si](c2ccc(C#N)cc2)(c2ccc(C#N)cc2)c2ccc(-c3ccc4c(c3)sc3ccccc34)cc2)cc1]

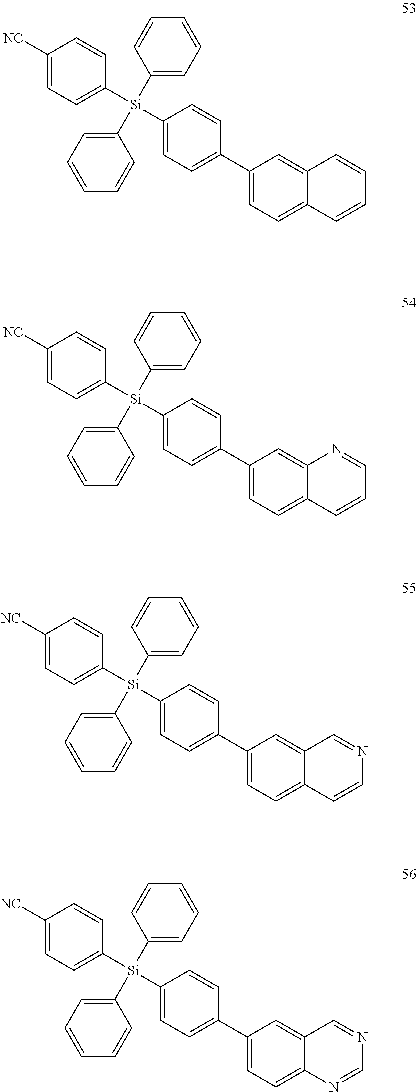 [SMILES: N#Cc1ccc([Si](c2ccccc2)(c2ccccc2)c2ccc(-c3ccc4ccccc4c3)cc2)cc1 ; N#Cc1ccc([Si](c2ccccc2)(c2ccccc2)c2ccc(-c3ccc4cccnc4c3)cc2)cc1 ; N#Cc1ccc([Si](c2ccccc2)(c2ccccc2)c2ccc(-c3ccc4ccncc4c3)cc2)cc1 ; N#Cc1ccc([Si](c2ccccc2)(c2ccccc2)c2ccc(-c3ccc4ncncc4c3)cc2)cc1]

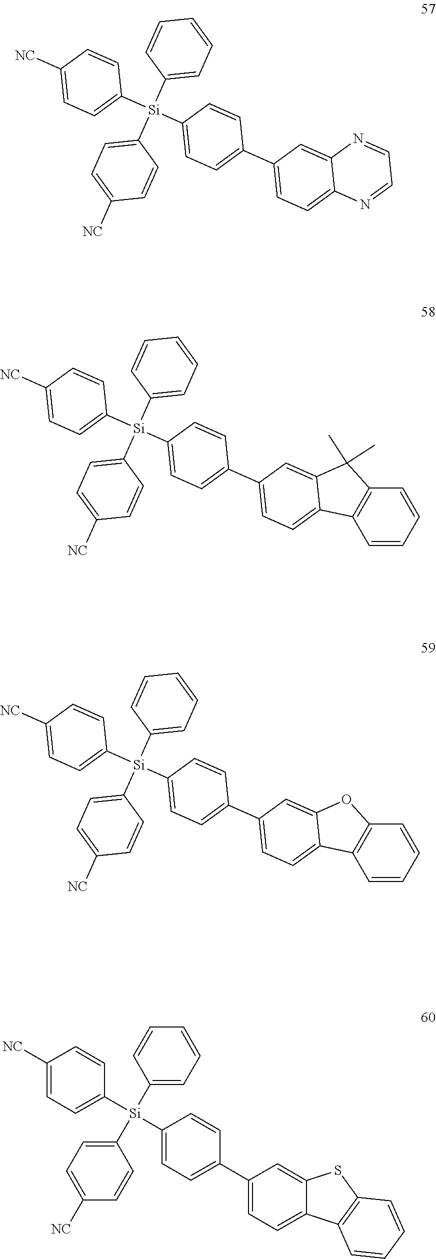 [SMILES: N#Cc1ccc([Si](c2ccccc2)(c2ccc(C#N)cc2)c2ccc(-c3ccc4nccnc4c3)cc2)cc1 ; CC1(C)c2ccccc2-c2ccc(-c3ccc([Si](c4ccccc4)(c4ccc(C#N)cc4)c4ccc(C#N)cc4)cc3)cc21 ; N#Cc1ccc([Si](c2ccccc2)(c2ccc(C#N)cc2)c2ccc(-c3ccc4c(c3)oc3ccccc34)cc2)cc1 ; N#Cc1ccc([Si](c2ccccc2)(c2ccc(C#N)cc2)c2ccc(-c3ccc4c(c3)sc3ccccc34)cc2)cc1]

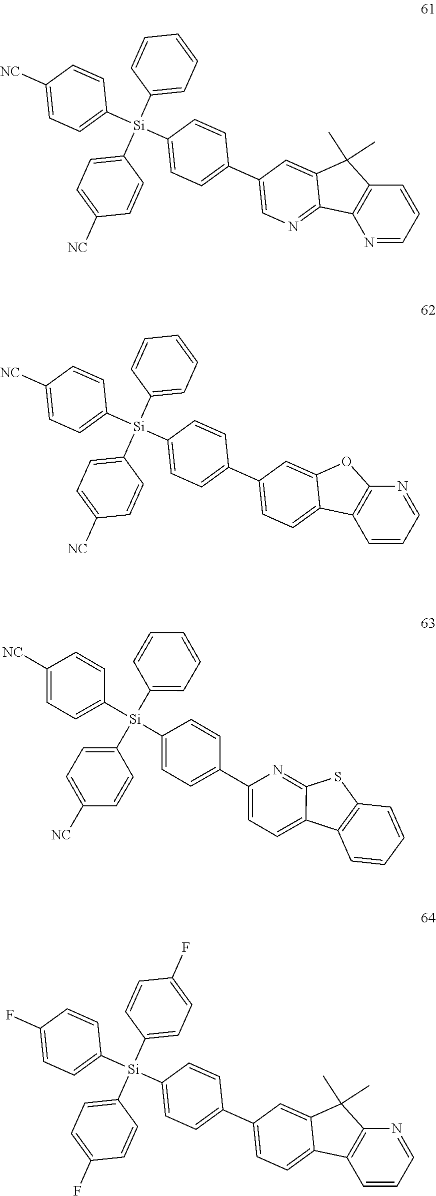 [SMILES: CC1(C)c2cccnc2-c2ncc(-c3ccc([Si](c4ccccc4)(c4ccc(C#N)cc4)c4ccc(C#N)cc4)cc3)cc21 ; N#Cc1ccc([Si](c2ccccc2)(c2ccc(C#N)cc2)c2ccc(-c3ccc4c(c3)oc3ncccc34)cc2)cc1 ; N#Cc1ccc([Si](c2ccccc2)(c2ccc(C#N)cc2)c2ccc(-c3ccc4c(n3)sc3ccccc34)cc2)cc1 ; CC1(C)c2cc(-c3ccc([Si](c4ccc(F)cc4)(c4ccc(F)cc4)c4ccc(F)cc4)cc3)ccc2-c2cccnc21]

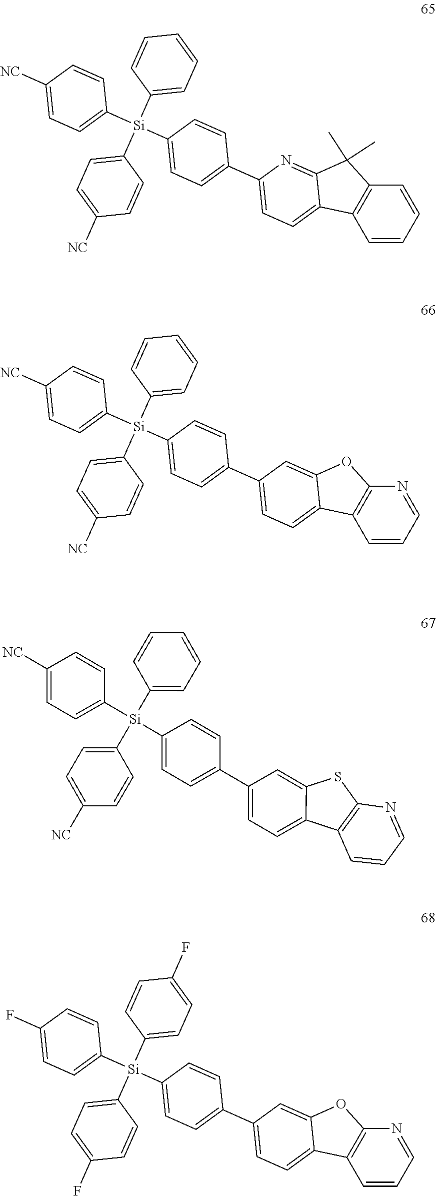 [SMILES: CC1(C)c2ccccc2-c2ccc(-c3ccc([Si](c4ccccc4)(c4ccc(C#N)cc4)c4ccc(C#N)cc4)cc3)nc21 ; N#Cc1ccc([Si](c2ccccc2)(c2ccc(C#N)cc2)c2ccc(-c3ccc4c(c3)oc3ncccc34)cc2)cc1 ; N#Cc1ccc([Si](c2ccccc2)(c2ccc(C#N)cc2)c2ccc(-c3ccc4c(c3)sc3ncccc34)cc2)cc1 ; Fc1ccc([Si](c2ccc(F)cc2)(c2ccc(F)cc2)c2ccc(-c3ccc4c(c3)oc3ncccc34)cc2)cc1]

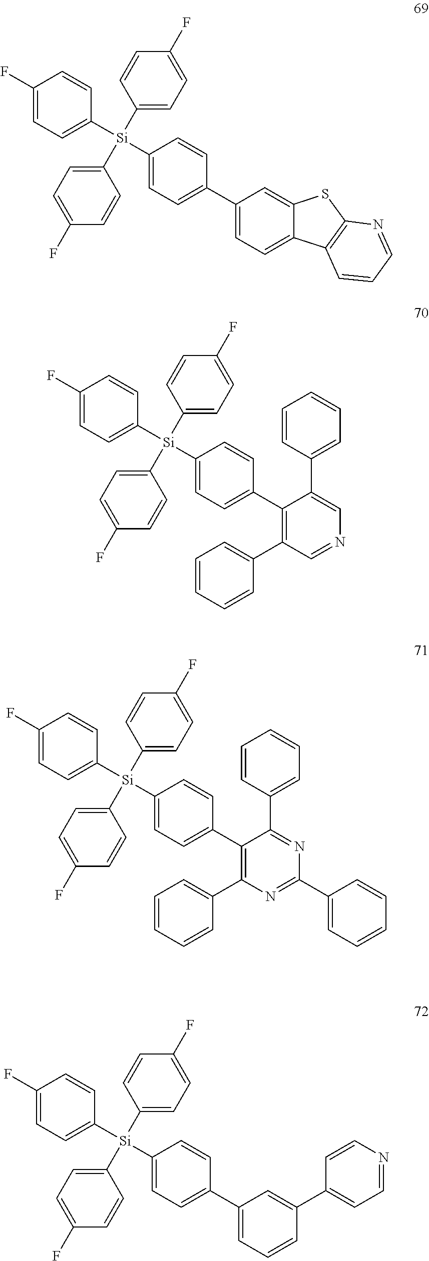 [SMILES: Fc1ccc([Si](c2ccc(F)cc2)(c2ccc(F)cc2)c2ccc(-c3ccc4c(c3)sc3ncccc34)cc2)cc1 ; Fc1ccc([Si](c2ccc(F)cc2)(c2ccc(F)cc2)c2ccc(-c3c(-c4ccccc4)cncc3-c3ccccc3)cc2)cc1 ; Fc1ccc([Si](c2ccc(F)cc2)(c2ccc(F)cc2)c2ccc(-c3c(-c4ccccc4)nc(-c4ccccc4)nc3-c3ccccc3)cc2)cc1 ; Fc1ccc([Si](c2ccc(F)cc2)(c2ccc(F)cc2)c2ccc(-c3cccc(-c4ccncc4)c3)cc2)cc1]

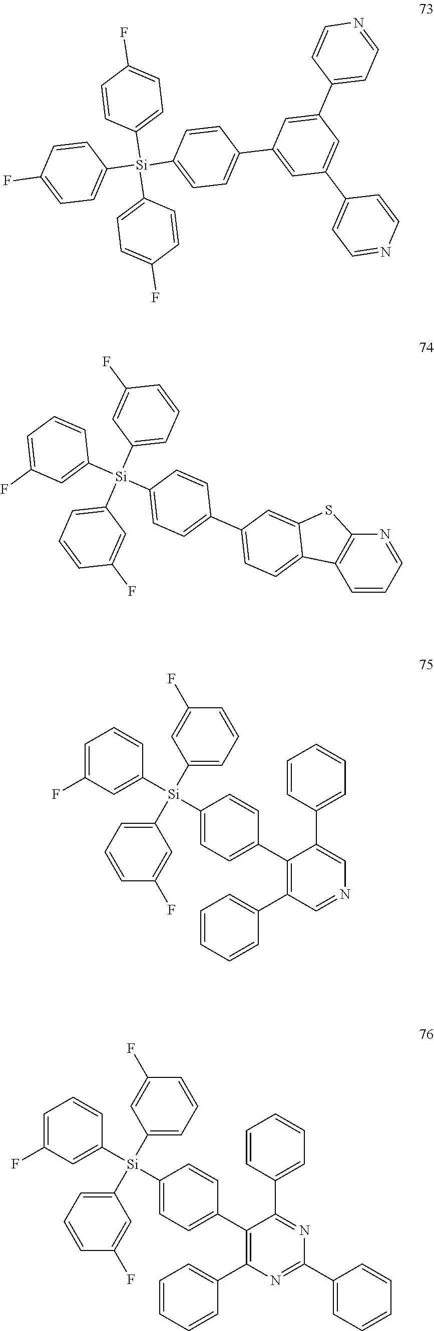 [SMILES: Fc1ccc([Si](c2ccc(F)cc2)(c2ccc(F)cc2)c2ccc(-c3cc(-c4ccncc4)cc(-c4ccncc4)c3)cc2)cc1 ; Fc1cccc([Si](c2ccc(-c3ccc4c(c3)sc3ncccc34)cc2)(c2cccc(F)c2)c2cccc(F)c2)c1 ; Fc1cccc([Si](c2ccc(-c3c(-c4ccccc4)cncc3-c3ccccc3)cc2)(c2cccc(F)c2)c2cccc(F)c2)c1 ; Fc1cccc([Si](c2ccc(-c3c(-c4ccccc4)nc(-c4ccccc4)nc3-c3ccccc3)cc2)(c2cccc(F)c2)c2cccc(F)c2)c1]

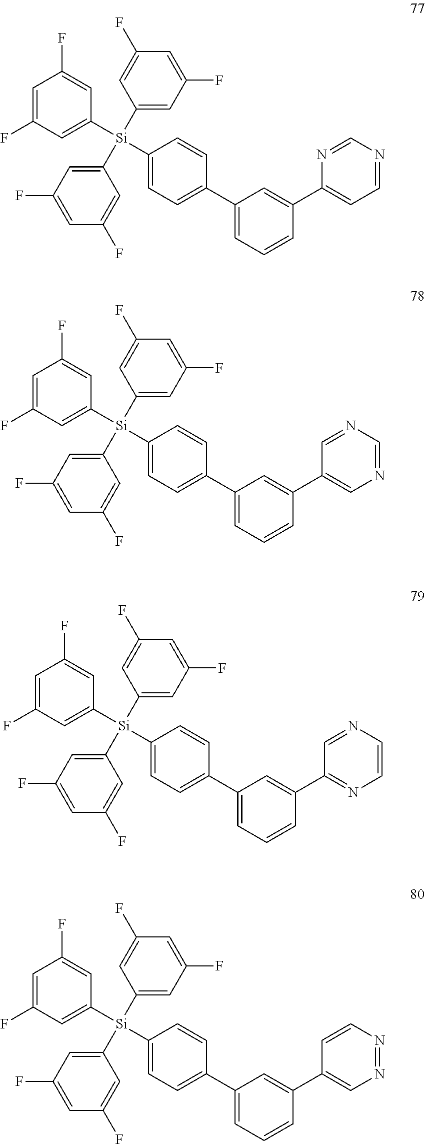 [SMILES: Fc1cc(F)cc([Si](c2ccc(-c3cccc(-c4ccncn4)c3)cc2)(c2cc(F)cc(F)c2)c2cc(F)cc(F)c2)c1 ; Fc1cc(F)cc([Si](c2ccc(-c3cccc(-c4cncnc4)c3)cc2)(c2cc(F)cc(F)c2)c2cc(F)cc(F)c2)c1 ; Fc1cc(F)cc([Si](c2ccc(-c3cccc(-c4cnccn4)c3)cc2)(c2cc(F)cc(F)c2)c2cc(F)cc(F)c2)c1 ; Fc1cc(F)cc([Si](c2ccc(-c3cccc(-c4ccnnc4)c3)cc2)(c2cc(F)cc(F)c2)c2cc(F)cc(F)c2)c1]

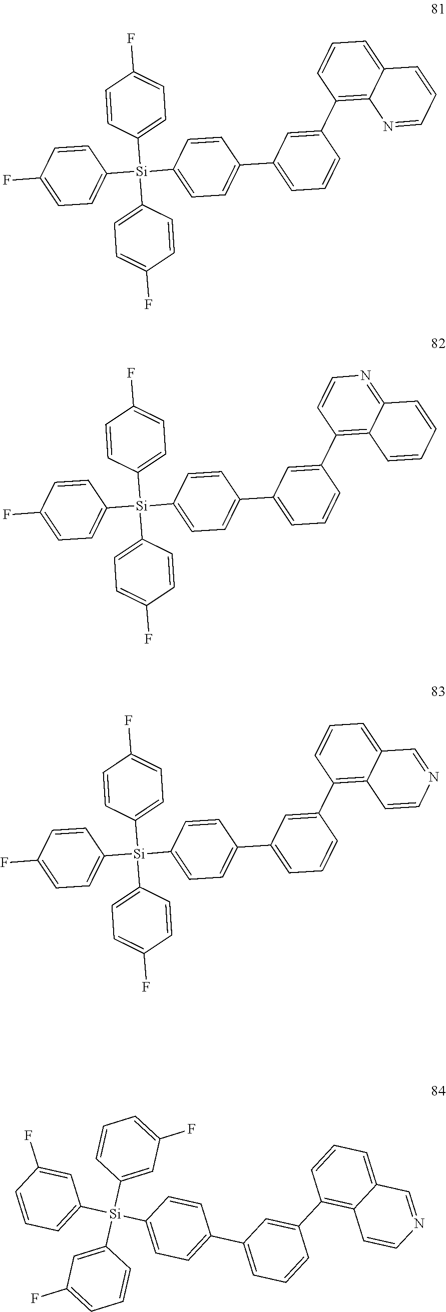 [SMILES: Fc1ccc([Si](c2ccc(F)cc2)(c2ccc(F)cc2)c2ccc(-c3cccc(-c4cccc5cccnc45)c3)cc2)cc1 ; Fc1ccc([Si](c2ccc(F)cc2)(c2ccc(F)cc2)c2ccc(-c3cccc(-c4ccnc5ccccc45)c3)cc2)cc1 ; Fc1ccc([Si](c2ccc(F)cc2)(c2ccc(F)cc2)c2ccc(-c3cccc(-c4cccc5cnccc45)c3)cc2)cc1 ; Fc1cccc([Si](c2ccc(-c3cccc(-c4cccc5cnccc45)c3)cc2)(c2cccc(F)c2)c2cccc(F)c2)c1]

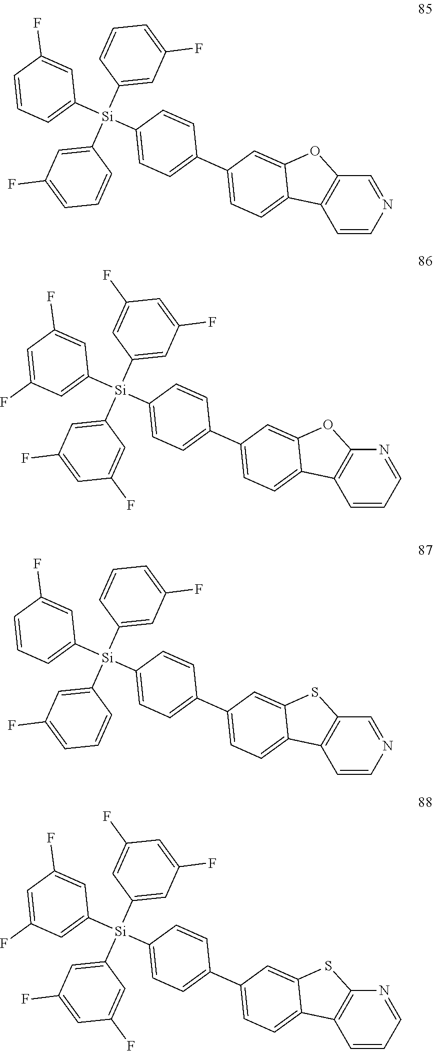 [SMILES: Fc1cccc([Si](c2ccc(-c3ccc4c(c3)oc3cnccc34)cc2)(c2cccc(F)c2)c2cccc(F)c2)c1 ; Fc1cc(F)cc([Si](c2ccc(-c3ccc4c(c3)oc3ncccc34)cc2)(c2cc(F)cc(F)c2)c2cc(F)cc(F)c2)c1 ; Fc1cccc([Si](c2ccc(-c3ccc4c(c3)sc3cnccc34)cc2)(c2cccc(F)c2)c2cccc(F)c2)c1 ; Fc1cc(F)cc([Si](c2ccc(-c3ccc4c(c3)sc3ncccc34)cc2)(c2cc(F)cc(F)c2)c2cc(F)cc(F)c2)c1]

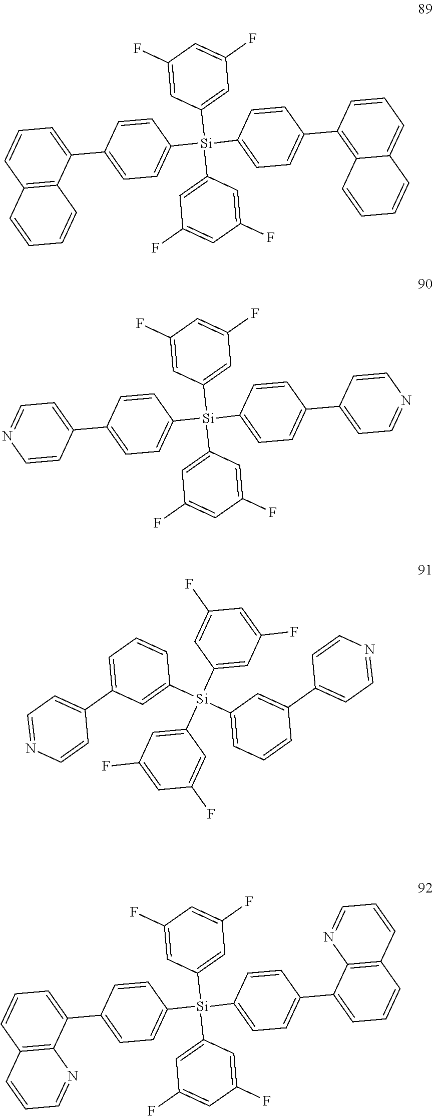 [SMILES: Fc1cc(F)cc([Si](c2ccc(-c3cccc4ccccc34)cc2)(c2ccc(-c3cccc4ccccc34)cc2)c2cc(F)cc(F)c2)c1 ; Fc1cc(F)cc([Si](c2ccc(-c3ccncc3)cc2)(c2ccc(-c3ccncc3)cc2)c2cc(F)cc(F)c2)c1 ; Fc1cc(F)cc([Si](c2cc(F)cc(F)c2)(c2cccc(-c3ccncc3)c2)c2cccc(-c3ccncc3)c2)c1 ; Fc1cc(F)cc([Si](c2ccc(-c3cccc4cccnc34)cc2)(c2ccc(-c3cccc4cccnc34)cc2)c2cc(F)cc(F)c2)c1]

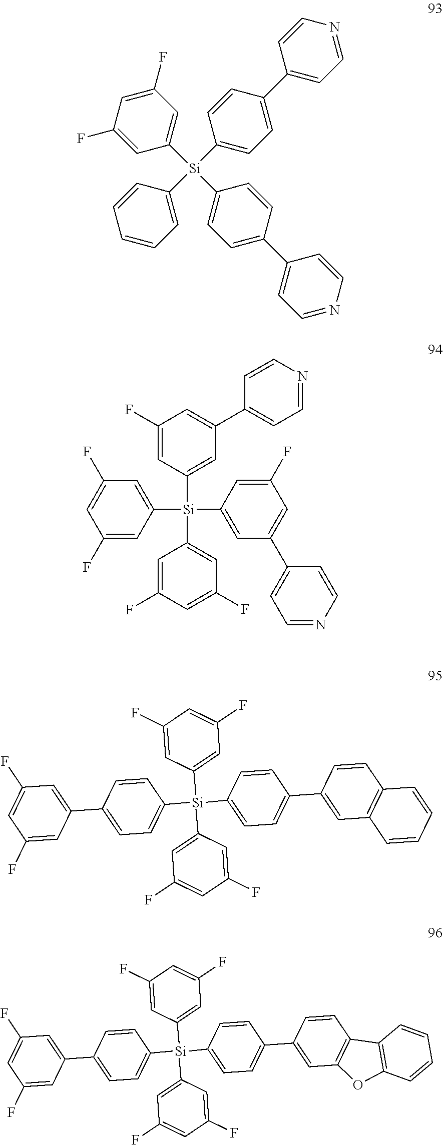 [SMILES: Fc1cc(F)cc([Si](c2ccccc2)(c2ccc(-c3ccncc3)cc2)c2ccc(-c3ccncc3)cc2)c1 ; Fc1cc(F)cc([Si](c2cc(F)cc(F)c2)(c2cc(F)cc(-c3ccncc3)c2)c2cc(F)cc(-c3ccncc3)c2)c1 ; Fc1cc(F)cc(-c2ccc([Si](c3ccc(-c4ccc5ccccc5c4)cc3)(c3cc(F)cc(F)c3)c3cc(F)cc(F)c3)cc2)c1 ; Fc1cc(F)cc(-c2ccc([Si](c3ccc(-c4ccc5c(c4)oc4ccccc45)cc3)(c3cc(F)cc(F)c3)c3cc(F)cc(F)c3)cc2)c1]

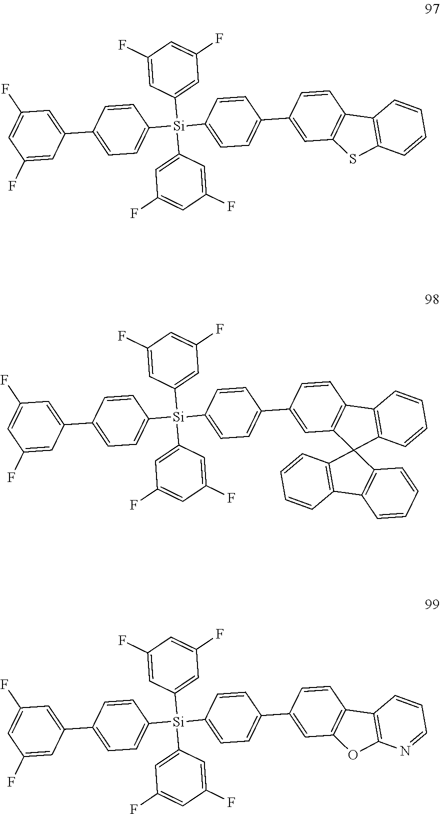 [SMILES: Fc1cc(F)cc(-c2ccc([Si](c3ccc(-c4ccc5c(c4)sc4ccccc45)cc3)(c3cc(F)cc(F)c3)c3cc(F)cc(F)c3)cc2)c1 ; Fc1cc(F)cc(-c2ccc([Si](c3ccc(-c4ccc5c(c4)C4(c6ccccc6-c6ccccc64)c4ccccc4-5)cc3)(c3cc(F)cc(F)c3)c3cc(F)cc(F)c3)cc2)c1 ; Fc1cc(F)cc(-c2ccc([Si](c3ccc(-c4ccc5c(c4)oc4ncccc45)cc3)(c3cc(F)cc(F)c3)c3cc(F)cc(F)c3)cc2)c1]

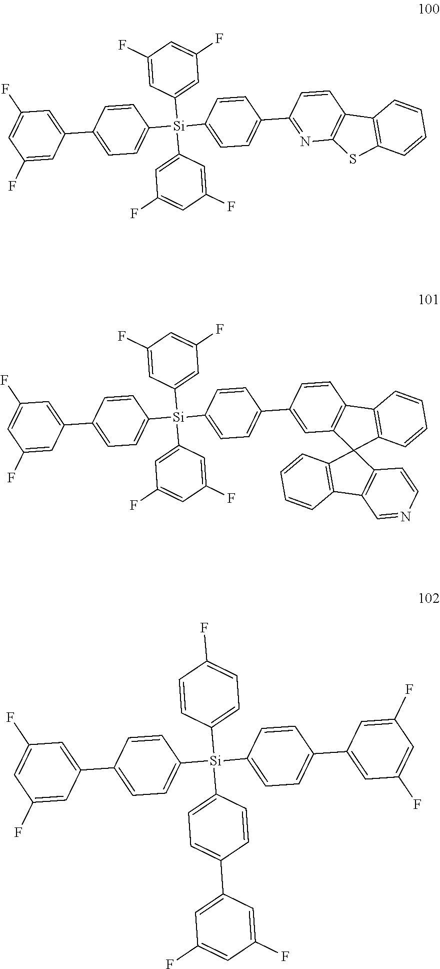 [SMILES: Fc1cc(F)cc(-c2ccc([Si](c3ccc(-c4ccc5c(n4)sc4ccccc45)cc3)(c3cc(F)cc(F)c3)c3cc(F)cc(F)c3)cc2)c1 ; Fc1cc(F)cc(-c2ccc([Si](c3ccc(-c4ccc5c(c4)C4(c6ccccc6-c6cnccc64)c4ccccc4-5)cc3)(c3cc(F)cc(F)c3)c3cc(F)cc(F)c3)cc2)c1 ; Fc1ccc([Si](c2ccc(-c3cc(F)cc(F)c3)cc2)(c2ccc(-c3cc(F)cc(F)c3)cc2)c2ccc(-c3cc(F)cc(F)c3)cc2)cc1]

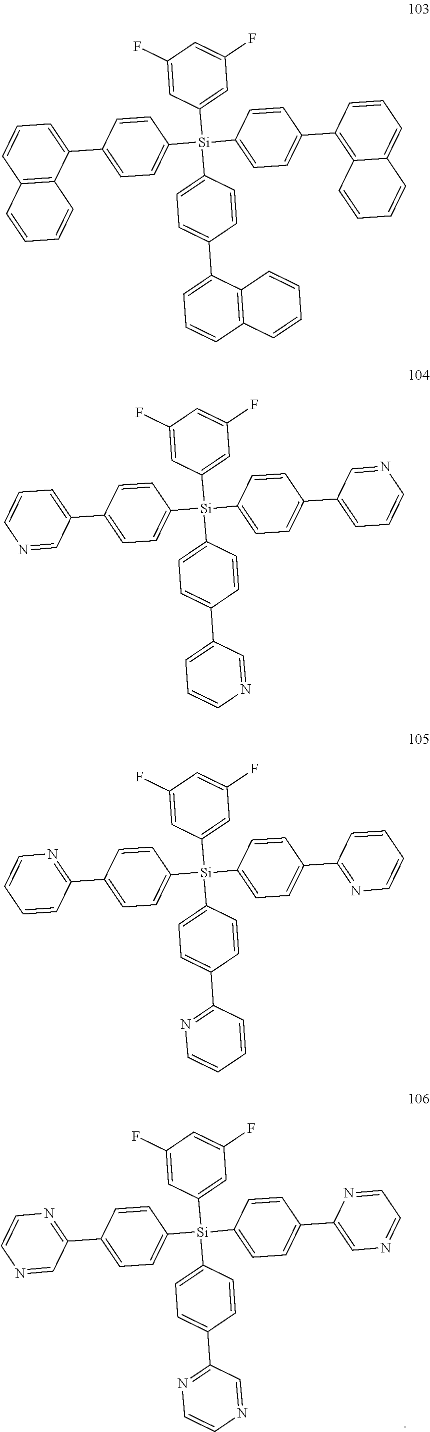 [SMILES: Fc1cc(F)cc([Si](c2ccc(-c3cccc4ccccc34)cc2)(c2ccc(-c3cccc4ccccc34)cc2)c2ccc(-c3cccc4ccccc34)cc2)c1 ; Fc1cc(F)cc([Si](c2ccc(-c3cccnc3)cc2)(c2ccc(-c3cccnc3)cc2)c2ccc(-c3cccnc3)cc2)c1 ; Fc1cc(F)cc([Si](c2ccc(-c3ccccn3)cc2)(c2ccc(-c3ccccn3)cc2)c2ccc(-c3ccccn3)cc2)c1 ; Fc1cc(F)cc([Si](c2ccc(-c3cnccn3)cc2)(c2ccc(-c3cnccn3)cc2)c2ccc(-c3cnccn3)cc2)c1]

18. A display panel comprising an organic light-emitting diode, wherein the organic light-emitting diode comprises an anode, a cathode arranged oppositely, a capping layer located on a side of the cathode away from the anode, and an organic layer located between the anode and the cathode; and the capping layer comprises the compound with low refractive index according to claim 1.

19. The display panel according to claim 18, wherein the capping layer is a double-layered capping layer, the double-layered capping layer comprises a low-refractive capping layer and a high-refractive capping layer, the low-refractive capping layer comprises the compound with low refractive index, the high-refractive capping layer contains a compound with high refractive index; and the compound with high refractive index has an N value greater than 1.9.

20. A display device, comprising the display panel according to claim 19.
